(19) United States
(12) Patent Application Publication
(10) Pub. No.: US 2026/0132899 A1
(43) Pub. Date: May 14, 2026

(54) Body Heat Powered Wearable Strobe Light Apparatus and Method

(71) Applicant: Erik Nathan Lamp, San Francisco, CA (US)

(72) Inventor: Erik Nathan Lamp, San Francisco, CA (US)

(21) Appl. No.: 19/362,354

(22) Filed: Oct. 18, 2025

Related U.S. Application Data
(60) Provisional application No. 63/719,092, filed on Nov. 11, 2024.

(51) Int. Cl. F21S 9/02; F21S 10/06; F21V 23/04; F21V 33/00; F21Y 115/10; H05B 45/31; H05B 47/155; H10N 10/17; H10N 10/82

(52) U.S. Cl. CPC F21S 9/02; F21S 10/06; F21V 23/0407; F21V 33/0008; H05B 45/31; H05B 47/155; H10N 10/17; H10N 10/82; F21Y 2115/10

(57) ABSTRACT

A body-heat-powered wearable strobe light is disclosed, integrated into clothing or accessories to enhance visibility and safety in low-light conditions. The system employs a thermoelectric generator (TEG) to convert heat from the wearer into electrical energy, which is conditioned by an energy-harvesting circuit and stored in an energy storage element such as a capacitor bank. An oscillator and driver circuit regulate power delivery to one or more light-emitting diodes (LEDs), producing a pulsed strobe effect. In some embodiments, maximum power point tracking (MPPT) control is used to optimize energy extraction from the TEG. The TEG may employ a modular, multi-stage design with thermoelectric pellets, conductive interconnects, and thermal substrates to enhance electrical output. System features may include adaptive strobe frequency control, waterproofing, flexible substrates, and integration of heat spreaders for improved thermal performance. This architecture provides a compact, durable, and maintenance-free lighting solution powered entirely by body heat, reducing reliance on batteries while ensuring continuous operation for outdoor and emergency use.

### BACKGROUND OF THE INVENTION

The necessity for wearable safety devices has become increasingly critical in modern society, particularly for individuals engaged in nocturnal outdoor activities such as jogging, cycling, or walking in low-visibility environments. Conventional safety lights for such purposes typically rely on batteries, which require periodic replacement or recharging. This dependence introduces several drawbacks, including potential downtime, inconvenient maintenance, limited water resistance, and the risk of failure during active use. Battery-related issues may compromise reliability at precisely the moments when visibility is most essential for safety.

To address these concerns, thermoelectric energy harvesting technology has emerged as a promising alternative. This technology exploits the temperature differential between the human body and the surrounding environment to generate electricity, offering a continuous and renewable power source. By removing the need for batteries, a thermoelectric-powered wearable light can reduce maintenance requirements, extend operational reliability, and eliminate risks associated with battery leakage or depletion.

Recent advancements in materials science and ultra-low-power electronics have made such systems feasible. Developments in thermoelectric modules, energy-harvesting circuits, ultra-low-power control and oscillator circuits, and high-efficiency light-emitting diodes (LEDs) enable the creation of devices that are lightweight, comfortable, water-resistant, and capable of producing sufficient brightness from harvested body heat. These innovations open the path for practical body-heat-powered strobe lights that improve safety while also aligning with sustainability goals by reducing reliance on disposable or rechargeable batteries.

### SUMMARY OF THE INVENTION

In one aspect, the invention pertains to a wearable strobe light system embedded in a garment or accessory, the system comprising: a thermoelectric generator (TEG) configured to convert body heat into electrical power; an energy harvester circuit configured to optimize the TEG's output and raise it to a usable voltage level; an energy storage element for accumulating harvested power; an oscillator circuit and driver circuit configured to control delivery of power; and at least one lighting device, such as a light-emitting diode (LED), arranged to emit a strobing signal for visibility and safety. The system is structurally integrated into clothing or accessories so as to remain lightweight, unobtrusive, and continuously powered by the wearer's thermal energy.

In another aspect, the invention relates to a method of operation in which a thermoelectric generator embedded within a garment or accessory continuously harvests thermal energy from the wearer, transfers it through an energy harvester circuit, and accumulates it in an energy storage element. The stored energy is then released under the control of an oscillator and driver circuit to power a lighting device in timed pulses, producing a strobe effect. This process provides a direct pathway from body heat to visible light, ensuring that signaling or safety illumination is maintained as long as a temperature gradient exists across the thermoelectric generator.

Together, these implementations emphasize safety, efficiency, reliability, waterproofing, and adaptability, ensuring that the system remains compact, reliable, and suited to a wide range of environments and garment types. These benefits, along with other specific advantages, are outlined in detail below.

Advantages of one implementation may include one or more of the following:

Sustainability and eco-friendliness: The system harnesses body heat as a renewable power source, eliminating disposable or rechargeable batteries. This reduces environmental waste, electronic pollution, and carbon footprint, aligning with global sustainability goals while providing a safer alternative to chemical-based storage cells.

Continuous and reliable operation: By drawing power directly from body heat, the system offers uninterrupted operation as long as a temperature gradient exists. Unlike battery-powered devices that can suddenly fail when depleted, this approach provides consistent reliability in critical safety scenarios while eliminating the need for recharging or replacement.

Convenience and user comfort: The integration of the TEG into lightweight garments ensures a maintenance-free, always-ready solution. The absence of bulky batteries or external packs maintains wearer comfort, mobility, and unobtrusiveness in both everyday and professional use.

Enhanced safety and visibility: High-intensity strobing improves wearer visibility in low-light or hazardous environments, alerting motorists, coworkers, or others nearby. Multiple LEDs may be employed to create distributed or patterned illumination, further enhancing visibility and signaling effectiveness.

Waterproofing and aquatic safety: Sealed garment-integrated design protects electronics against moisture, ensuring reliable operation even when immersed in water. Eliminating batteries avoids leakage or failure risks, making the system safe for aquatic use.

Durability and ruggedness: Reinforced thermoelectric modules, flexible substrates, and integrated heat spreaders enhance resistance to impacts, bending, and environmental stresses. These design elements increase structural stability while preserving long-term reliability for daily wear and active use.

Power efficiency and brightness optimization: An energy harvester circuit matches the TEG's output to its optimal operating point, maximizing harvested energy. The strobe circuit regulates discharge from the energy storage element to optimize both pulse brightness and strobe frequency, ensuring maximum visibility within the available energy budget.

Cost-effectiveness: By eliminating the recurring expense of disposable or rechargeable batteries, the device reduces lifetime ownership costs while maintaining functionality over extended use.

Versatility and adaptability: The technology can be incorporated into a wide range of garments and accessories-including shirts, vests, wristbands, armbands, headbands, helmets, belts, and harnesses-supporting diverse applications for humans and animals.

### BRIEF DESCRIPTION OF DRAWINGS

FIG. 1a illustrates a top view of a basic embodiment of the thermoelectric generator clothing system, depicting principal components and their interconnections. Section lines shown in this view correspond to the cross-sectional FIG. 1c-1e.

FIG. 1b illustrates a bottom view of a basic embodiment of the thermoelectric generator clothing system, depicting principal components and their interconnections. Section lines shown in this view correspond to the cross-sectional FIG. 1c-1e.

FIG. 1c illustrates a cross-sectional side view of the basic thermoelectric generator clothing system, taken along one of the section lines marked in FIG. 1a-b, showing the thermoelectric generator positioned between garment layers and connected to the electronics compartment, with key components and their interconnections.

FIG. 1d illustrates a cross-sectional front view of the basic thermoelectric generator clothing system, taken along a section line marked in FIG. 1a-b, showing the side of the thermoelectric generator from which the electrical output wires extend into the electronics compartment.

FIG. 1e illustrates a cross-sectional back view of the basic thermoelectric generator clothing system, taken along a section line marked in FIG. 1a-b, showing the opposite side of the thermoelectric generator and its integration into the garment structure.

FIG. 2a illustrates a top view of another embodiment of the thermoelectric generator clothing system, featuring heat sinks/spreaders and an advanced electrical system with multiple LEDs that may be individually controlled. Section lines shown in this view correspond to the cross-sectional FIG. 2c-2e.

FIG. 2b illustrates a bottom view of another embodiment of the thermoelectric generator clothing system, featuring heat sinks/spreaders and an advanced electrical system with multiple LEDs that may be individually controlled. Section lines shown in this view correspond to the cross-sectional FIG. 2c-2e.

FIG. 2c illustrates a cross-sectional side view of the advanced thermoelectric generator clothing system, taken along one of the section lines marked in FIG. 2a-b, showing the thermoelectric generator positioned between garment layers, with heat sinks/spreaders attached, and its connections to the electronics compartment.

FIG. 2d illustrates a cross-sectional front view of the advanced thermoelectric generator clothing system, taken along a section line marked in FIG. 2a-b, showing the side of the thermoelectric generator from which electrical output wires extend into the electronics compartment.

FIG. 2e illustrates a cross-sectional back view of the advanced thermoelectric generator clothing system, taken along a section line marked in FIG. 2a-b, showing the opposite side of the thermoelectric generator and the integration of heat sinks/spreaders within the garment structure.

FIG. 3a illustrates a top view of how the LEDs and associated electronic circuits are embedded within the compartment of the clothing or accessory, and how these electronic assemblies may be coated in a sealant for water resistance. Section lines indicated in this view correspond to the cross-sectional illustrations of FIGS. 3c and 3d.

FIG. 3b illustrates a bottom view of the clothing or accessory showing the compartment containing the embedded LEDs and electronic circuits, which may be coated in a sealant for water resistance. Section lines in this view also correspond to the cross-sectional illustrations of FIGS. 3c and 3d.

FIG. 3c illustrates a cross-sectional side view of the clothing or accessory, taken along a section line of FIGS. 3a-b, showing the LEDs and electronic circuits embedded within the compartment and depicting how a protective sealant may encapsulate these assemblies for water resistance.

FIG. 3d illustrates a cross-sectional side view similar to FIG. 3c, taken along a section line of FIGS. 3a-b, but with the electronic assemblies additionally enclosed within a protective casing, providing enhanced mechanical durability and environmental protection.

FIG. 4a illustrates a cross-sectional view of an exemplary strobe-light safety band, such as a sweatband, showing the thermoelectric generator, electronic circuits, and lighting device embedded within the layered band structure. This cross-section corresponds to section lines indicated in FIGS. 4b and 4c.

FIG. 4b illustrates a top view of the strobe-light safety band, depicting the placement and interconnection of the thermoelectric generator, electronics compartment, and lighting device. Section lines in this view indicate the cross-section shown in FIG. 4a.

FIG. 4c illustrates a bottom view of the strobe-light safety band, showing the thermoelectric generator, electronics compartment, and lighting device as integrated into the band structure. Section lines in this view likewise indicate the cross-section shown in FIG. 4a.

FIG. 5a illustrates a sectional view of a fixed multi-stage thermoelectric generator (TEG) design without a heat sink or spreader, showing multiple stages integrated into a single structure.

FIG. 5b illustrates a sectional view of a modular multi-stage TEG design composed of stacked modules, without the implementation of heat sinks or spreaders.

FIG. 5c illustrates a sectional view of the modular multi-stage TEG design with heat sinks/spreaders thermally coupled to the outermost modules to enhance heat transfer.

FIG. 5d illustrates a sectional view of the internal structure of a single stage/module of the multi-stage TEG, showing thermoelectric pellets positioned between substrates and interconnects.

FIG. 6a illustrates a 3-D view of the modular multi-stage thermoelectric generator (TEG) design with modules electrically connected in series, optimizing output voltage.

FIG. 6b illustrates a sectional view of the modular multi-stage TEG design with modules electrically connected in series, optimizing output voltage.

FIG. 6c illustrates a sectional view of the modular multi-stage TEG design with modules electrically connected in parallel, optimizing output current.

FIG. 6d illustrates a sectional view of the modular multi-stage TEG design with modules electrically connected in a hybrid series/parallel configuration, balancing voltage and current for system optimization.

FIG. 7 illustrates a flowchart providing a system architecture view of the simplified body-heat-powered strobe light.

FIG. 8a illustrates an exemplary circuit schematic of a basic strobe light design in which the oscillator and driver circuit are combined with a capacitor bank and an LED, powered from a voltage source.

FIG. 8b illustrates an exemplary circuit schematic of a basic strobe light design in which the oscillator and driver circuit are combined with a capacitor bank and an LED, powered from a current source.

FIG. 9 FIG. 9 illustrates a flowchart providing a system architecture view of an advanced design for the body-heat-powered strobe light and the interconnection of its components.

### DETAILED DESCRIPTION OF THE INVENTION

The one embodiment comprises a body-heat-powered thermoelectric strobe light system configured for integration into garments or accessories, including shirts, jackets, vests, wristbands, headbands, armbands, belts, harnesses, and helmets. The system enhances the visibility of a wearer human or non-human in low-light environments by harnessing the wearer's body heat as the sole power source for generating bright, attention-getting strobe illumination, without reliance on chemical batteries. It has the ability to convert body heat directly into electrical power for continuous strobe operation. The system comprises a garment-integrated compartment, a thermoelectric generator (TEG) (100), an energy harvester circuit, an energy storage element, oscillator and driver circuitry, and one or more lighting devices.

The compartment may be formed as part of the clothing itself or provided as a separate insert, serving both as a housing for the electronics and as a mounting structure for the TEG (100). The TEG (100) converts the temperature difference between the wearer's body and the surrounding air into electrical power, which is conditioned by the energy harvester to maximize extraction and elevate the voltage to usable levels. Harvested power is accumulated in the energy storage element, which supplies both instantaneous current to the lighting device and operating power for the oscillator and driver circuits.

In simplified embodiments, the storage capacitor also functions as the oscillator's timing element, creating a self-regulating architecture in which the strobe frequency scales naturally with available body heat. In more advanced embodiments, the oscillator is decoupled from the storage capacitor and operates on a regulated rail, enabling stable programmable frequency control, optional multi-LED sequencing, and adaptive brightness.

Thermal management features including flexible or rigid substrates, thermally conductive spreaders, insulating sealants, and adhesive bonding strategies may be incorporated to optimize heat transfer through the TEG (100) while maintaining wearer comfort and garment durability. The clothing structure may further include sealing or encapsulation to protect the electronics from moisture or mechanical stress, enabling reliable use in athletic, outdoor, or aquatic environments.

Electrically, the design minimizes component count and quiescent power draw, while ensuring that nearly all harvested energy is directed toward producing visible light. Thermally, the use of optimized substrates, heat spreaders, and bonding strategies reduces parasitic resistances and maximizes the temperature differential across the thermoelectric generator (100). Mechanically, the integration of adhesives, sealants, and layered fabrics provides both durability and water resistance without adding bulk. At the system level, features such as adaptive strobe frequency, modular driver circuits, and scalable multi-LED configurations allow the device to maintain visibility across varying body heat conditions while conserving energy. Together, these measures ensure that the strobe light delivers reliable, bright illumination under real-world environmental constraints while remaining practical for wearable applications.

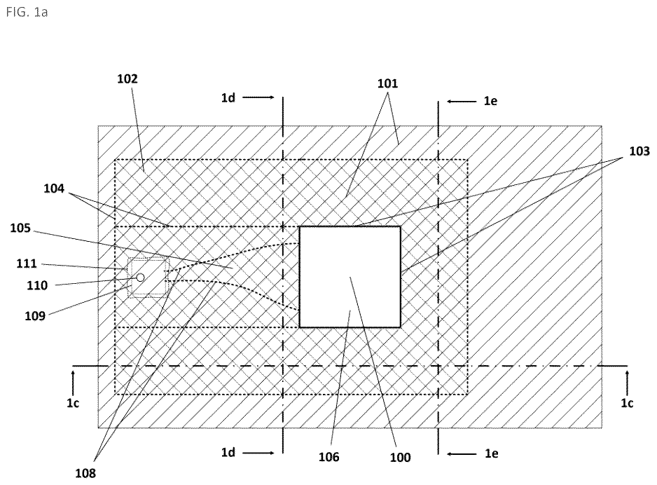

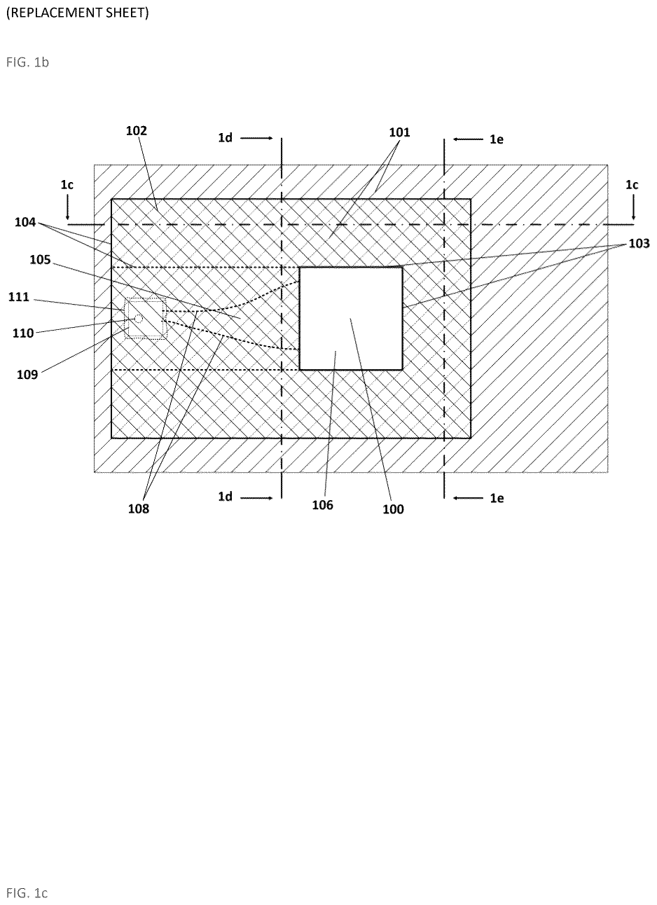

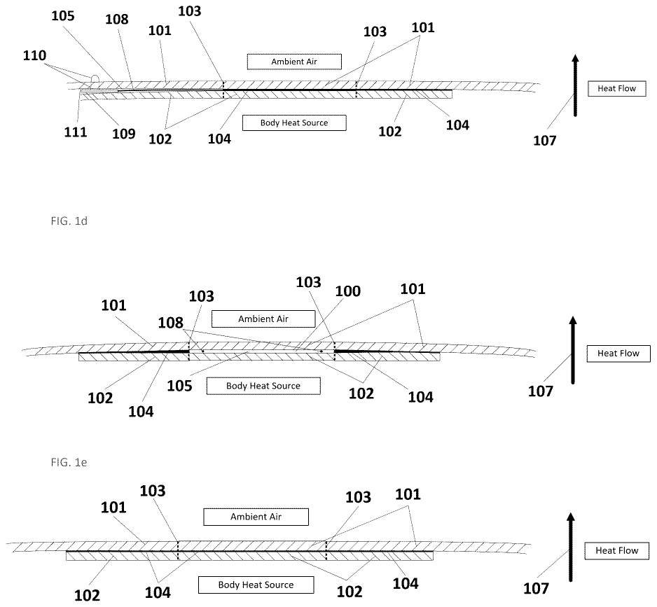

FIGS. 1a-1e collectively illustrate the foundational embodiment of the body-heat-powered strobe light system, integrated into a multi-layer garment structure. FIG. 1a presents a top view of the assembly as seen from the garment's outer surface, revealing the layout of key components. The primary clothing layer (101) forms the visible exterior. The thermoelectric generator (TEG) (100) is centrally positioned, bonded at its perimeter by the TEG bonding adhesive sealant (103). From the TEG (100), output wires (108) extend into the electronics compartment (105), which is formed by a secondary clothing layer (102, not fully visible in this view) and sealed with compartment bonding adhesive sealant (104). The lighting device or LED (110) protrudes through the primary layer, secured by protective sealant (300). Section lines indicate the planes for the subsequent cross-sectional figures.

FIG. 1b illustrates the corresponding bottom, or wearer-facing, view. This perspective highlights the secondary clothing layer (102) that encloses the electronics compartment and interfaces directly with the wearer's body for optimal heat collection. The TEG (100) is visible through its sealant bond (103), with its output wires (108) connecting to the electronic circuit board (109) inside the compartment. The board is protected by a protective sealant coating (111), and interconnect wires (204) link it to the LED (110).

FIG. 1c provides a side cross-sectional view, cutting horizontally through the assembly to reveal the vertical stacking and thermal pathway. This view clearly shows the primary (101) and secondary (102) layers forming the compartment, with the TEG (100) sandwiched between them. The TEG's thermal substrates (106) are visible on its top and bottom sides. The direction of the essential heat flow (107) is explicitly shown, traveling upward from the body, through the TEG (100), and into the ambient air. The path of the TEG output wires (108) into the compartment to connect with the circuit board (109) is also detailed.

FIG. 1d offers a front cross-sectional view, cutting through the assembly from9999 front to back. This angle emphasizes the sealing strategy around the electronics compartment (105) and the routing of the TEG output wires (108), which appear in cross-section as they extend into the page. The TEG bonding adhesive sealant (103) surrounding the TEG (100) and the compartment bonding adhesive sealant (104) joining the fabric layers are clearly depicted, highlighting their role in creating a sealed, protected environment for the electronics.

FIG. 1e presents a rear cross-sectional view, complementing FIG. 1d by showing the opposite side of the assembly. This view further illustrates the robustness of the bonding and sealing strategy, showing how the adhesive sealants (103, 104) fully encapsulate the edges of the TEG (100) and the electronics compartment (105), ensuring mechanical stability, thermal insulation, and water resistance from all sides.

### Thermal Management and Heat Transfer

Body heat is captured at a thermal substrate on the side of the TEG (100) that is nearest the body heat source. If the modular multi-stage TEG design is used, heat is transferred among the TEG modules via a thermal interface material positioned in between the thermal substrates of each module. Heat from the last TEG module is vented into the ambient air by the last thermal substrate. The TEG (100) generates electrical power by this heat flow and outputs it at the positive and negative electrical terminals.

Thermal substrates (106) are thermally conductive, electrically insulating plates forming the hot- and cold-side interfaces of the TEG (100), which may be rigid (e.g., ceramic such as alumina or aluminum nitride) or flexible (e.g., polymer films, coated foils). To thermally connect all pellets in parallel, they are mounted between two thermal substrates (106).

Flexible substrates improve mechanical compliance, reduce cracking risk under bending/impact, and enhance wearer comfort; in some implementations they also act as integrated thermal spreaders. Each stage thus incorporates a high-temperature-side substrate and a low-temperature-side substrate selected to balance thermal conduction, durability, and garment integration.

In enhanced embodiments, heat sinks or spreaders (503) are incorporated to improve thermal performance. A thermally conductive plate is attached to the ambient-facing (cold) side of the TEG (100), increasing heat rejection to surrounding air. This enhances cooling, improves the temperature gradient across the TEG (100), and thereby increases electrical output. The spreader also strengthens the mechanical interface with the primary garment layer. Suitable materials include copper, aluminum, or carbon-based composites.

On the body-facing (hot) side, another spreader collects heat from the wearer more effectively than direct TEG (100) contact alone, again boosting the TEG's output. Like the top-side component, it also reinforces the garment attachment. The spreaders (503) are bonded to both sides of the TEG (100). Adhesive such as a rubber sealant is applied at non-TEG-contact regions to secure the spreaders to the garment fabric, while the thermal contact surfaces use a thermal interface material (TIM) (202) to ensure efficient conduction.

The heat sink or spreader (503) itself may be fabricated from a material of high thermal conductivity, including copper, aluminum, or graphite, and may be rigid or flexible. In addition to enhancing heat transfer, the spreader reinforces the TEG structure, which may otherwise be brittle due to ceramic substrates. This reinforcement increases durability and longevity under physical stress, such as drops or impacts. A flexible spreader can also conform to the garment and wearer's body, improving ergonomics, comfort, and output power.

Body heat is first absorbed by the lower spreader, passes through the TEG (100) via its substrates (or multiple stacked modules in a modular multi-stage design), and is then transferred into the upper spreader before being dissipated to the ambient environment. Heat sinks and spreaders (503), when attached with suitable thermal interface materials (202), further increase power output by improving heat collection from the body and heat rejection to the ambient. Flexible spreaders additionally allow the TEG (100) to conform to garment contours, maintaining comfort while sustaining efficient heat transfer.

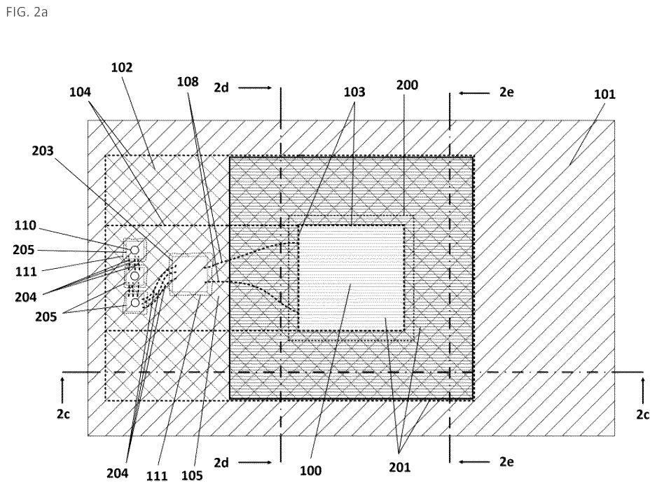

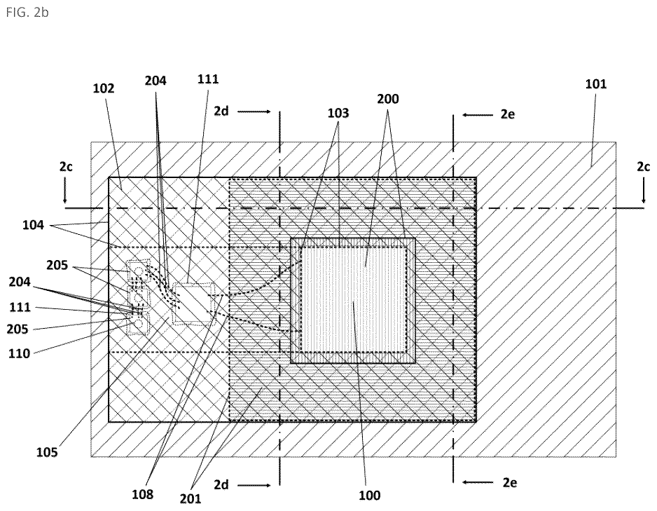

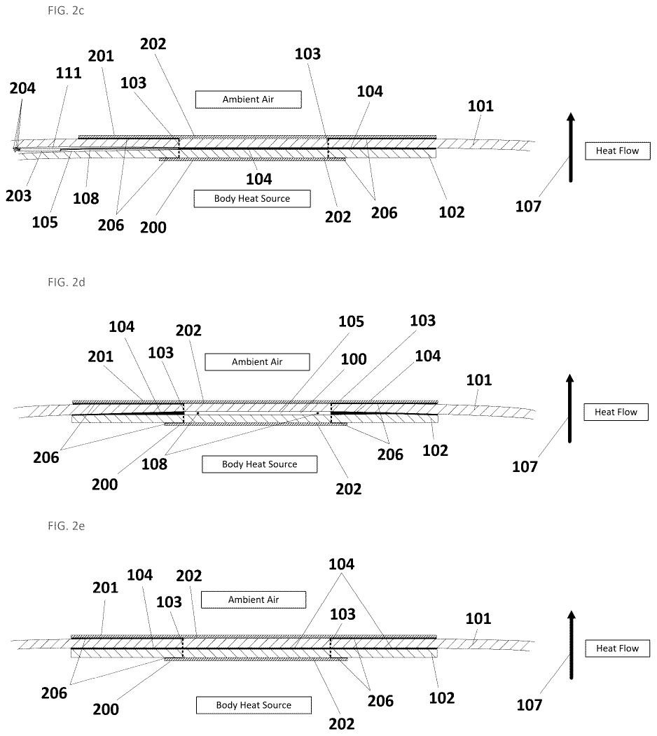

FIGS. 2a through 2e illustrate an advanced embodiment of the thermoelectric generator (TEG) clothing system that incorporates heat sinks or heat spreaders to enhance thermal performance compared to the basic design shown in FIG. 1. This enhanced configuration is integrated into a multi-layer garment structure similar to the basic embodiment but includes external thermal management components to improve power generation efficiency.

FIG. 2a presents the top view of the system, showing the outer surface of the garment with the primary clothing layer (101) visible. The ambient-facing heat sink or heat spreader (201) is prominently displayed as a thermally conductive plate attached to the cold side of the TEG (100). This spreader increases the surface area for heat rejection to the surrounding air, thereby enhancing the cooling effect and improving the temperature gradient across the TEG (100). The spreader serves dual purposes: it strengthens the mechanical interface with the garment fabric and facilitates more efficient heat dissipation. Suitable materials for this component include copper, aluminum, or carbon-based composites known for high thermal conductivity.

The TEG's electrical output leads (108) are shown extending from the generator toward the main electronic circuit board housed within the electronics compartment (105). These leads carry the harvested electrical power to the circuit board for conditioning and storage. Interconnect wires then route power from the main circuit board (203) to multiple LED modules (not fully visible in this view but indicated by their presence elsewhere in the system). The lighting devices are positioned to protrude through the primary clothing layer at arbitrary locations on the garment surface, enabling external visibility of the strobe illumination.

The top-side heat spreader (201) is visibly larger than its body-facing counterpart, reflecting its role in maximizing heat rejection to ambient air. Component labels include the primary clothing layer (101), TEG (100), electronics compartment (105), TEG output wires (108), heat spreader bonding adhesive (206), thermal interface material regions (202, not individually labeled but implied at TEG-spreader interfaces), and section indicators.

FIG. 2b depicts the bottom or wearer-facing side of the garment system. This view shows the secondary or cover clothing layer (102), which encloses the electronics compartment from beneath and provides structural support for component integration. The body-side heat sink or heat spreader (200) is visible in this view and appears smaller in surface area than the ambient-side spreader shown in FIG. 2a. This spreader is attached to the hot side of the TEG (100) the side that faces the wearer's body and functions to collect heat more effectively than direct TEG (100) contact alone would permit.

The body-side spreader (200) enhances thermal coupling between the wearer's skin and the TEG (100) by providing a low-resistance thermal pathway. Like its ambient-side counterpart, it also reinforces the garment attachment and adds mechanical stability to what may otherwise be a brittle TEG structure, particularly if ceramic substrates are used. The spreader may be fabricated from rigid materials such as copper or aluminum, or from flexible alternatives such as graphite foils or composite laminates that conform better to body contours and improve wearer comfort.

The electronics compartment (105) is shown as a sealed enclosure formed by bonding the secondary layer to the primary layer using an adhesive sealant. The compartment houses the main electronic circuit board (203), interconnecting wires, and associated control electronics. Component labels include the secondary/cover clothing layer (102), TEG (100), body-side heat spreader (200), electronics compartment (105), adhesive sealant for spreader bonding (206), and thermal interface material (202) applied between the TEG substrates and spreaders.

FIG. 2c provides a side cross-sectional view along the section line indicated in FIGS. 2a and 2b, illustrating the layered construction of the system and the direction of heat flow from the body heat source to ambient air. Heat flow is represented by an upward arrow (107) on the right side of the diagram, indicating the vertical path from the wearer's body through the TEG (100) and out into the surrounding environment.

The body heat source is shown as the origin of thermal energy. Heat enters the system through the body-side heat spreader (200), which is thermally bonded to the lower substrate of the TEG (106) using a thermal interface material (TIM) (202). The TIM may consist of a thermal pad, paste, compound, or thermally conductive adhesive selected to minimize thermal resistance at the interface while maintaining durability and ease of assembly.

The TEG (100) comprises thermoelectric pellets sandwiched between thermal substrates (106) on both sides. Heat flows vertically through the pellets, generating electrical power via the Seebeck effect. The upper substrate of the TEG interfaces with the ambient-side heat spreader (201) through another layer of thermal interface material (202), ensuring efficient thermal conduction into the spreader.

From the spreader, heat is rejected into the ambient air. The spreaders are secured to the garment layers using an adhesive sealant (206) applied at non-contact regions specifically, along the edges and sides where thermal bonding is not required. This sealant provides mechanical retention, environmental sealing against moisture, and thermal insulation to prevent lateral heat leakage that would reduce the effective temperature gradient across the TEG (100).

The primary clothing layer (101) forms the outer surface of the garment, while the secondary/cover layer (102) encloses the system from below, creating the electronics compartment (105) between them. The compartment houses the main electronic circuit board (203, not visible in this particular section) and LED modules. The TEG's electrical output wires (108) are shown extending from the generator into the compartment, where they connect to the circuit board for power harvesting and conditioning.

Adhesive sealant is visible at multiple locations: bonding the spreaders to the fabric layers (206), sealing the compartment edges, and potentially coating the TEG perimeter to suppress lateral heat loss (206). The thermal substrates (106) of the TEG (100) are indicated as the thermally conductive, electrically insulating plates that sandwich the thermoelectric pellets.

FIG. 2d presents a front cross-sectional view, taken from the perspective of looking toward the TEG (100) from its output lead side. This view highlights the structure of the electronics compartment relative to the TEG (100) and shows how electrical connections are routed through the garment layers.

In this cross-section, the TEG (100) is visible with its output wires (108) extending horizontally into the page toward the electronics compartment (105). The wires are represented as large dots or circular cross-sections, indicating that they extend perpendicularly out of the plane of the drawing. This perspective emphasizes the size and depth of the electronics compartment, which provides adequate internal volume to house circuit boards, wiring, and LED modules without excessive bulk.

The ambient-side heat spreader (201) is shown above the TEG (100), bonded to the primary clothing layer (101) using adhesive sealant (206). Thermal interface material (202) is applied between the TEG's upper substrate (106) and the spreader to ensure efficient heat transfer. Similarly, the body-side heat spreader (200) is visible below the TEG (100), bonded to the secondary clothing layer (102) with adhesive sealant and thermally coupled to the TEG's lower substrate via TIM (202).

The adhesive bonds around the compartment edges are depicted with dotted or dashed lines, illustrating how the primary and secondary fabric layers are sealed together to form a water-resistant enclosure. The section shows the compartment's cross-sectional depth and the spatial arrangement of components within the multi-layer garment structure. Heat flow is again indicated by an upward arrow (107), reinforcing the vertical thermal pathway from body to ambient air.

FIG. 2e illustrates a rear cross-sectional view, showing the back bonding of the TEG assembly and the integration of spreaders, substrates, and fabric layers into a unified structure. This view complements FIGS. 2c and 2d by providing an alternative sectional perspective that emphasizes the sealing and mechanical integration of the system.

In this section, the TEG (100) is positioned centrally between the two heat spreaders. The ambient-side spreader (201) is bonded to the primary clothing layer (101), while the body-side spreader (200) is bonded to the secondary layer (102). Thermal interface material (202) is applied at the junctions between the TEG substrates (106) and both spreaders, ensuring low thermal resistance along the vertical heat flow path indicated by the arrow (107).

Adhesive sealant (206) is shown coating the edges of the spreaders and the sides of the TEG (100), providing both environmental sealing and mechanical bonding. This sealant fills gaps around the perimeter of the assembly, preventing moisture ingress and suppressing lateral heat leakage that would otherwise reduce system efficiency. The TEG's thermal substrates (106), though not individually visible in all regions of this view, are implied as the layers directly interfacing with the thermoelectric pellets.

The electronics compartment (105) is again visible, formed by the bonded fabric layers and sealed at its edges. The rear bonding arrangement ensures that the entire TEG, spreader, and electronics assembly is integrated as a durable unit capable of withstanding physical stress, environmental exposure, and repeated washing or wear cycles. The output wires (108) are shown extending from the TEG (100) toward the compartment, maintaining electrical connectivity for power delivery to the circuit board.

Material such as a thermal pad, paste, or compound is applied between the TEG substrates and the heat sinks or spreaders to ensure efficient thermal conduction. Suitable TIMs (202) include thermal pads, pastes/compounds, or thermally conductive adhesives. TIM fills the direct thermal paths between the TEG (100) and spreaders, while sealant material insulates and secures the sides. Additional TIM is applied between the spreader surfaces and the module substrates to reduce contact resistance and ensure efficient heat transfer.

Modules are physically stacked with thermal interface material (TIM) (202) disposed between adjacent module substrates to reduce inter-module thermal resistance. The module edges may be filled or coated with a thermally insulating sealant (502) (e.g., rubber or silicone). This sealant suppresses lateral heat leakage, enhances water resistance, and protects against electrical short-circuiting between pellets in the presence of moisture. In addition to insulation, the sealant may be used to bond the modular stack to the garment, simplifying integration and increasing robustness.

The available body heat is determined by the wearer's temperature and the total thermal resistance between the body and the TEG (100). The total thermal resistance includes contributions from the wearer's skin, any intervening clothing or fabrics, optional heat sinks or spreaders, hair or fur, and the ambient environment. On the air side, thermal resistance arises from conduction, convection, and radiation, influenced by air temperature, airflow velocity, garment movement, and the effective contact area.

For maximum efficiency, the TEG's own thermal resistance is designed to match the sum of the body-side and air-side resistances. Matching resistances maximizes the temperature drop across the TEG (100) and increases both voltage and power output. To achieve this balance, a multi-stage design either fixed or modular may be employed.

The efficiency of the multi-stage thermoelectric generator (TEG) design depends on its ability to preserve a strong temperature gradient across the thermoelectric pellets while minimizing parasitic losses. Each stage is configured to balance thermal resistance and electrical output such that the overall TEG (100) operates close to its optimal thermal load line. By stacking stages thermally in series, the total thermal resistance can be tuned to match the combined resistance of the body-side and air-side heat transfer paths, thereby maximizing the effective voltage and power generated for a given temperature differential.

Structural features further contribute to efficiency. Flexible or thin ceramic substrates (106) reduce parasitic resistance and improve mechanical compliance, allowing closer thermal contact with both the wearer's body and the surrounding environment. The use of hybrid bonding strategies such as insulating adhesives applied along module edges combined with thermal interface materials (202) (pads, pastes, or conductive adhesives) applied between thermal substrates (106) and heat spreaders suppresses lateral heat leakage while ensuring low-resistance vertical heat flow. These measures enhance temperature differential retention and protect against moisture ingress, which could otherwise degrade performance.

Collectively, these thermal and structural design strategies maximize the usable Seebeck voltage, improve conversion efficiency, and ensure that the TEG (100) can deliver stable output power in the variable and dynamic thermal environments characteristic of wearable applications.

### Garment Integration and Structural Design

The system may be implemented into any clothing or clothing accessory, allowing for versatility in use across different applications for both humans and animals. The thermoelectric generator (TEG) (100), which may be a modular multi-stage design, is bonded between two layers of clothing or clothing accessory by its sides via rubber sealant or similar adhesive material.

The two layers of clothing or accessory—a primary layer (101) and a secondary/cover layer (102), form a compartment for the electronics to be stored in. The primary layer (101) is the outer layer of the clothing or accessory, such as the visible outer layer of a vest. The secondary layer (102) is the inner or cover layer of the clothing or accessory, such as the inner layer of a vest.

The secondary layer (102) may be attached not as a full layer, but as an added patch to the primary layer with an adhesive or sealant that may be water resistant, flexible, and thermally insulating, such as a rubber sealant. The secondary layer (102) may also be stitched to the primary layer. The compartment may be localized on or cover the entire clothing or accessory. The compartment may be created by attaching the secondary layer as a patch to the primary layer or be in between the layers of multi-layered clothing or accessories.

The compartment stores and protects the electronics. These electronics may include the electronic circuit board(s) that collect and store energy, and power and control the lighting device, wires/cables between the TEG (100) and the electronic circuit board(s), and the lighting device(s). The compartment may be made of a material that provides water resistance for the electronics. The compartment may be made of a flexible material to provide a form of comfort and form fitting for the wearer. The electronics in the compartment may be coated in a rubber sealant for additional water resistance.

The TEG (100) may be attached to the clothing or accessory by its sides by an adhesive, which may be a rubber sealant, to reduce the whole system's mass, size, and weight. The adhesive must be able to bind the side material of the TEG (100), which may be a thermal substrate, to the material of the clothing or accessory. The adhesive may be water resistant, flexible, and thermally insulating, such as a rubber sealant. This enables a strong bond between the TEG (100) and clothing or accessory material when the wearable strobe light is under stress by the environment or the wearer. This may include physical activities in either dry or wet weather.

A thermally insulating adhesive may be applied along the sides of the TEG (100) to secure the device to the clothing and provide environmental sealing, while also preventing lateral heat leakage that would reduce thermal efficiency. The TEG (100) may further be bonded through attachment to a heat spreader or heat sink.

The heat sink or spreader (503) itself may be fabricated from a material of high thermal conductivity, including copper, aluminum, or graphite, and may be rigid or flexible. In addition to enhancing heat transfer, the spreader reinforces the TEG structure, which may otherwise be brittle due to ceramic substrates. This reinforcement increases durability and longevity under physical stress, such as drops or impacts. A flexible spreader can also conform to the garment and wearer's body, improving ergonomics, comfort, and output power.

Finally, the multi-layer fabric design may further incorporate adhesives and sealants to provide water resistance and mechanical flexibility, while maintaining strong bonds between the TEG (100), spreaders, and fabric layers. The clothing is adaptable across garments including shirts, jackets, vests, socks, wristbands, headbands, harnesses, and helmets, enabling versatile use for humans or animals.

The lighting device (110), such as an LED, may be attached to the primary layer (101) of the clothing or accessory with an adhesive, such as a rubber sealant. The adhesive may be applied to the lighting device on the compartment side of the primary layer. The lighting device may go through the primary layer to allow it to stick out of the clothing or accessory. The LED (110) is positioned through a cut-out in the fabric layer, allowing external visibility while remaining mechanically bonded to the fabric by the surrounding sealant.

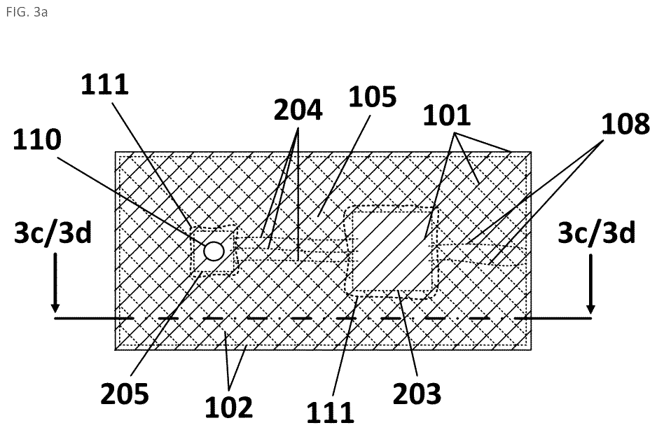

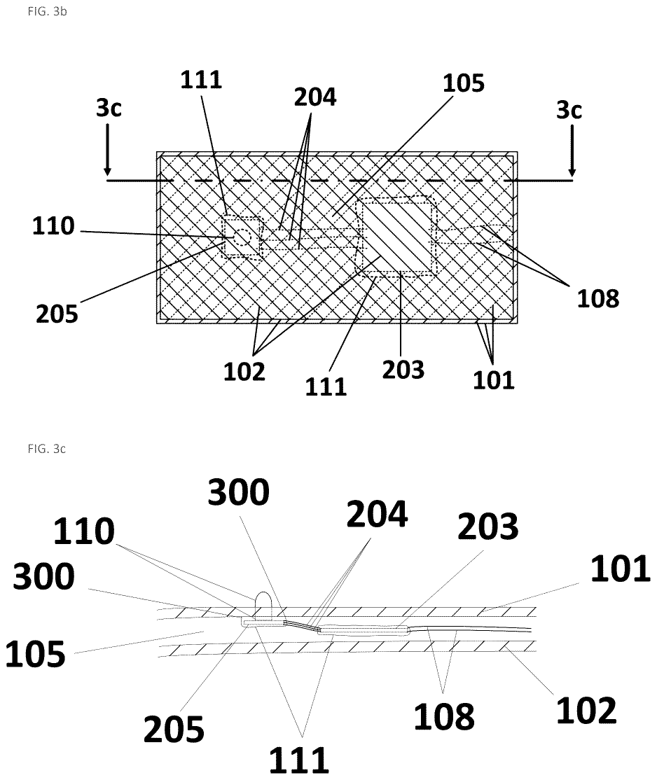

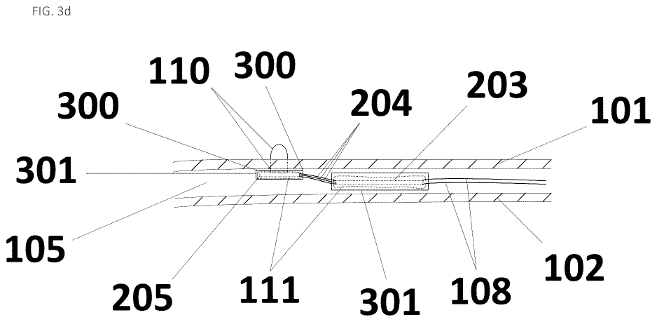

FIGS. 3a-3d provide focused views of the electronics compartment, illustrating the specific methods for protecting the circuit boards and integrating the lighting device, independent of the TEG and heat spreaders shown in previous figures. These figures highlight the packaging strategies that ensure long-term reliability in demanding environments.

FIG. 3a presents a top view of the electronics compartment, looking down through the primary clothing layer (101). This view reveals the internal layout, showing the main electronic circuit board (203) housed within the compartment. Interconnect wires (204) are shown routing from the main board towards a secondary LED module (205), which carries the lighting device. The LED itself is positioned through a cut-out in the primary fabric layer, allowing for external visibility. A protective sealant coating (111) is shown encapsulating the circuit boards, forming a conformal barrier over their surfaces and components. Section lines indicate the planes for the cross-sectional views in subsequent figures.

FIG. 3b illustrates the corresponding bottom view, depicting the underside of the compartment as formed by the secondary/cover clothing layer (102). This view shows the relationship between the primary and secondary layers and how they enclose the electronics. The outlines of the internal components, including the circuit board and wiring, are visible through the secondary layer, emphasizing the compact and integrated nature of the design.

FIG. 3c provides a cross-sectional view, cutting through the assembly to show the internal structure. This view clearly depicts the electronics compartment (105) as the cavity formed between the primary clothing layer (101) and the secondary clothing layer (102), sealed at the edges by a compartment bonding adhesive sealant. Inside, both the main electronic circuit board (203) and the LED module (205) are fully coated in a protective sealant coating (111), which adheres tightly to all component surfaces. This coating provides a flexible yet robust barrier that prevents water ingress and offers a degree of shock absorption. The lighting device or LED (110) is shown protruding through a cut-out hole in the primary layer. It is mechanically bonded and environmentally sealed to the fabric by a dedicated protective sealant for mounting (300) applied around its base. TEG output wires (108) are shown entering the compartment, delivering harvested power from the thermoelectric generator, while interconnect wires (204) complete the connection to the LED module.

FIG. 3d shows an alternative cross-sectional view of the same assembly, illustrating a key variation in the protection strategy. In this embodiment, the circuit boards are housed within a discrete protective enclosure (301). This optional enclosure, which may be made of plastic, rubber, or metal, provides an additional layer of defense against physical stresses such as drops, impacts, or abrasion. As in FIG. 3c, the LED (110) is secured to the primary clothing layer (101) with mounting sealant (300) and protrudes through the fabric. This view demonstrates the dual-layer protection strategy sealant plus enclosure that safeguards the electronics against both environmental and mechanical hazards.

The figures show a protective architecture that is efficient in terms of space, weight, and durability. By relying on passive sealing methods such as silicone or rubber coatings and optional enclosures, the system avoids bulky mechanical fasteners, keeping the design thin, flexible, and comfortable for the wearer. This balance of protection, reliability, and comfort ensures that the electronic subsystems remain functional across a wide range of real-world environments, from athletic use to aquatic immersion.

This compartment approach also emphasizes lightweight construction, compact size, and long-term reliability in wearable applications. By relying on passive sealing methods such as silicone coatings or adhesive bonding, the system avoids bulky enclosures or mechanical fasteners, keeping the design thin and flexible for user comfort. Encapsulation with sealant provides water resistance and shock protection while adding minimal mass. When combined with an optional enclosure, the electronics gain further resilience against compression or impact, without significantly increasing size or weight.

Together, these measures deliver a protective architecture that is efficient in terms of space, weight, and durability, while ensuring that the electronic subsystems are safeguarded without compromising wearability. This balance of protection, reliability, and comfort enables the body-heat-powered strobe light system to perform consistently across a wide range of real-world environments.

The system may be embodied in the form of an armband, wristband, or headband, which may be used as an athletic sweatband. The band (400) may be stitched together, acting as both a primary and secondary layer, forming a flat toroidal-like structure with a hollowed inside space that serves as the compartment to contain the electronics. The band may be made of a stretchable fabric to enhance fit for the wearer. A hole may be cut out of the band to accommodate the TEG (100).

The hollow interior of the band serves as the electronics compartment, wrapping around from one side of the TEG (100) to the other. Within this compartment, the TEG's output wires (108) are routed and connected to the electronic circuit board (109), which contains the energy harvesting and strobe-driving electronics. The lighting device (e.g., an LED) (110) is positioned on the opposite side of the band from the TEG (100), ensuring that light emission is directed outward while the TEG maintains close contact with the wearer's body. The LED (110) protrudes through the top layer of the band via a small cut-out hole.

This basic wearable embodiment is designed to maximize efficiency while keeping the form factor compact and lightweight. Because no external heat sinks or spreaders are used, thermal transfer occurs directly through the TEG (100) bonded to the fabric. This minimizes parasitic materials, and reduces weight and bulkiness of the wearable device.

The dual-layer band structure doubles as both a garment and an electronics compartment, eliminating the need for additional housings. The electronics are arranged in close proximity to the TEG (100), reducing wiring resistance and parasitic losses. The LED (110), chosen for its high luminous efficacy and low forward current, is positioned opposite the TEG so that heat and light functions are spatially separated but electrically efficient.

Rubber sealant serves a dual role: securing the TEG (100) to the garment and providing both water resistance and mechanical reinforcement. By also coating the circuit boards, the sealant allows the system to maintain long-term reliability without bulky enclosures or protective cases. This not only preserves energy by reducing thermal barriers but also improves durability under sweat, moisture, and impact.

Overall, the band-form configuration demonstrates that efficiency in wearable strobe-light systems extends beyond electronic circuits. Through careful integration of the TEG (100), electronics, and garment structure, this embodiment achieves a low-weight, low-loss design that maximizes visibility while minimizing material complexity and energy waste.

One advantage of embodiments without external heat sinks or spreaders is compactness. Because such designs omit external heat sinks or spreaders, the entire thermoelectric generator (TEG) clothing system can be made thinner, lighter, and more flexible. The TEG (100) is bonded directly between layers of fabric, with no additional bulk from metal or graphite spreaders. This results in a slimmer compartment profile that is more comfortable for the wearer and less visually intrusive when integrated into garments such as wristbands, headbands, or vests.

By contrast, the addition of heat sinks or spreaders, while enhancing thermal performance, may increase overall system thickness and stiffness, making the garment bulkier and potentially less flexible. The basic configuration without spreaders therefore represents the most compact embodiment, prioritizing ergonomics and low-profile integration over maximum thermal efficiency. This compact design is particularly suited for applications where wearer comfort, discretion, and minimal added weight are the most important considerations.

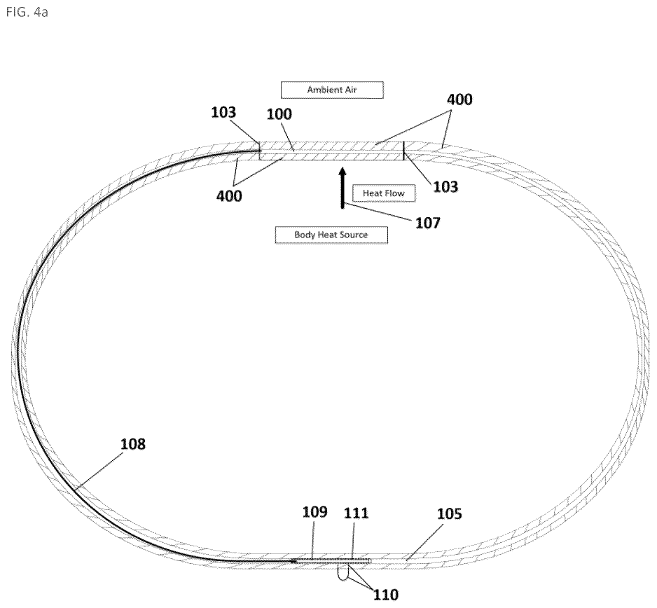

FIGS. 4a-4c illustrate a practical and compact realization of the invention in the form of a wearable band, such as an armband, wristband, or headband, which may also function as an athletic sweatband. This embodiment demonstrates the system's versatility and its ability to be integrated into a minimal, form-fitting accessory.

FIG. 4a provides a cross-sectional view of the band-form device, revealing its unique construction. The band itself (400) is a multi-layer fabric structure that is stitched or bonded together, acting as both the primary and secondary clothing layer to form a flat, toroidal-like structure with a hollow interior. This hollow interior serves as the electronics compartment (105). A hole is cut out of the band to directly accommodate the thermoelectric generator (TEG) (100), which is secured at its sides with an adhesive sealant (103). The hollow compartment wraps around from one side of the TEG (100) to the other, allowing for efficient internal routing of the TEG output wires (108). These wires connect the TEG (100) to the electronic circuit board (109) housed within the band. The lighting device or LED (110) is positioned on the opposite side of the band from the TEG (100). This strategic placement ensures that the light emission is directed outward for maximum visibility while the TEG maintains close, unobstructed contact with the wearer's body for optimal heat harvesting. The LED (110) protrudes through the top layer of the band via a small cut-out hole.

FIG. 4b presents a top view of the band, emphasizing the interface between the TEG (100) and the multi-layered fabric. The TEG (100) is shown seated within its cut-out, secured around its perimeter by the adhesive sealant (103). From this perspective, the arrangement of the TEG and the compartment relative to the band's overall geometry is clear. The TEG output leads (108) are shown being routed from the TEG (100) towards the edges of the compartment and down into the page, tracing the path they take through the hollow interior to reach the electronics.

FIG. 4c illustrates a bottom view of the band, showing the wearer-facing side. This view clearly depicts the placement of the electronic circuit board (109) and the LED (110) on the side opposite the TEG (100). The TEG output wires (108) are shown coming from the edges of the compartment to connect to the circuit board. The board is protected by a protective sealant coating (111), and the LED (110) protrudes out through the top fabric layer, confirming the spatially separated but electrically connected arrangement of the heat-harvesting and light-emitting components.

This band-form configuration exemplifies a highly efficient and user-centric design. The dual-layer band structure eliminates the need for additional housings, reducing weight and complexity. The electronics are arranged in close proximity to the TEG (100) within the hollow compartment, minimizing wiring resistance and parasitic losses. The use of rubber sealant serves a dual role: securing the TEG (100) to the garment while providing water resistance and mechanical reinforcement, which is essential for withstanding sweat, moisture, and the impacts of physical activity. By omitting external heat sinks or spreaders, this embodiment achieves a low-weight, low-loss design that maximizes visibility and wearer comfort, demonstrating a successful optimization of the core invention for a specific, popular product form factor.

### Thermoelectric Generator Design and Configuration

The thermoelectric generator (TEG) (100) may employ a modular multi-stage design. Each stage includes many coupled pairs of P-type and N-type thermoelectric pellets (500) electrically connected in series and thermally connected in parallel. The pellets (500) may employ a thermoelectric material optimized for body-temperature operation, such as bismuth telluride. Each coupled pair generates a voltage proportional to the temperature difference across it and the material's Seebeck coefficient; the stage output voltage is the sum of the series-connected pairs.

Each stage (504) consists of multiple P-type and N-type semiconductor pellets (500) connected electrically in series with an electrically conductive interconnect/substrate (501) and thermally in parallel with a thermal substrate (106). The pellets are sandwiched between a thermal substrate (106) on its high-temperature side and a thermal substrate (106) on its low-temperature side. This structural unit forms the basis for both the modular and fixed designs.

P-type and N-type thermoelectric pellets (500) are formed from a thermoelectric material optimized for body-temperature operation, such as bismuth telluride. Electrically conductive interconnects/substrates (501) copper or equivalent conductors are used to connect adjacent P-type and N-type pellets (500) in series.

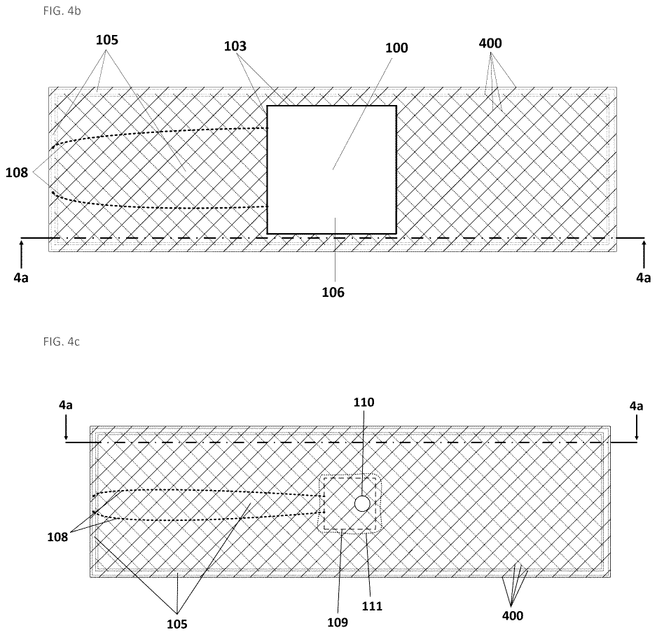

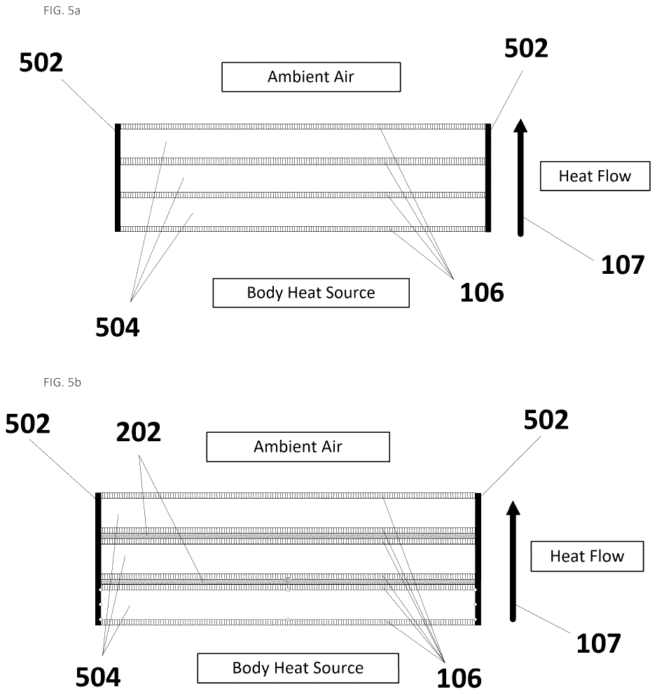

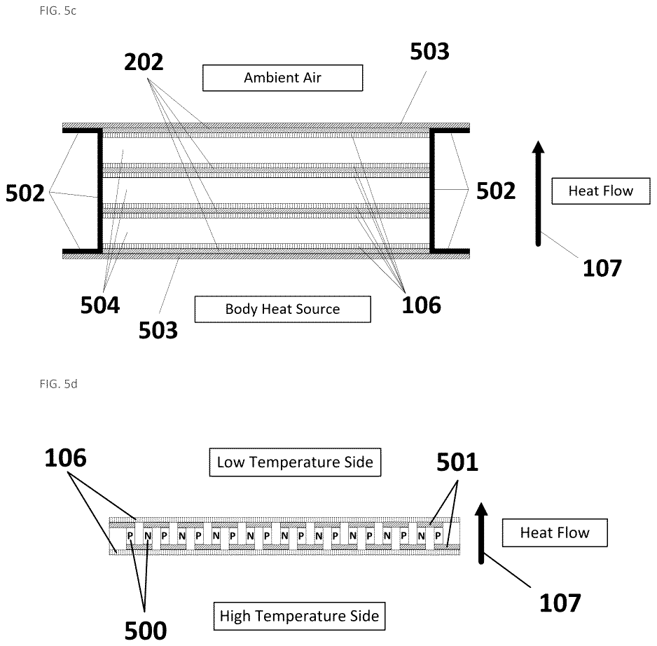

FIGS. 5a-5d illustrate exemplary multi-stage thermoelectric generator (TEG) embodiments for the wearable strobe-light clothing system, showing both fixed (monolithic) and modular configurations.

FIG. 5a depicts a fixed multi-stage TEG in which multiple stages are formed within a single integrated structure. In this embodiment, internal thermal substrates (106) separate the pellet layers within the monolithic block. The device includes thermally insulating sealant (502) applied around the perimeter, which simultaneously suppresses lateral heat leakage, improves water resistance, and bonds the TEG (100) directly to the garment. The internal pellet structure (500) is shown in horizontal layers, with heat flow (107) directed vertically from the body heat source toward the ambient air.

FIG. 5b illustrates a modular multi-stage TEG composed of discrete thermoelectric modules (504) stacked together. Each module is a self-contained unit featuring thermal substrates (106), pellet structures (500), and thermally insulating sealant (502) applied along the edges. Thermal interface material (202) is disposed between adjacent module substrates to minimize inter-module thermal resistance, ensuring efficient heat transfer through the stack. The heat flow (107) again travels vertically from the body heat source to the ambient air.

FIG. 5c shows the modular multi-stage configuration enhanced with external heat sinks or spreaders. Heat sinks/spreaders (503) are thermally bonded to the outermost module substrates on both the high-temperature (body-facing) and low-temperature (ambient-facing) sides using thermal interface material (202). The thermally insulating sealant (502) coats the edges of the TEG modules and the undersides of the spreaders, unifying the construction while maintaining lateral thermal insulation. The pellet structure (500) and thermal substrates (106) remain visible in the stacked layers, with heat flow (107) directed through the entire assembly.

FIG. 5d provides a detailed sectional view of a single thermoelectric stage or module (504), which forms the fundamental building block of the modular designs. The stage consists of multiple coupled pairs of P-type and N-type thermoelectric pellets (500), typically made from bismuth telluride optimized for body-temperature operation. These pellets (500) are electrically connected in series but thermally connected in parallel between two thermal substrates (106)—one on the high-temperature side (facing the body heat source) and one on the low-temperature side (facing ambient air). The heat flow (107) is directed vertically through the substrates and pellets, which generate voltage proportional to the temperature difference across them due to the Seebeck effect. The thermal substrates (106) may be rigid ceramics such as alumina or aluminum nitride, or flexible alternatives such as polymer films or coated foils, selected to balance thermal conduction, durability, and mechanical compliance for wearable integration.

The multi-stage design may be fixed (monolithic) or modular. In the fixed embodiment, multiple pellet layers are built into a single integrated structure, with internal thermal substrates (106) separating the stages. Heat flows vertically through the stacked pellet layers, with minimal lateral loss, producing a stronger temperature differential across the TEG (100). This arrangement provides a low-resistance thermal path while maximizing electrical output. A thermally insulating sealant (502) may be applied around the perimeter to suppress lateral heat leakage, improve water resistance, and bond the TEG (100) directly to the garment, reducing weight and simplifying integration.

In the modular approach, each stage is a discrete thermoelectric module (504). Modules are physically stacked with thermal interface material (TIM) (202) disposed between adjacent module substrates to reduce inter-module thermal resistance. The module edges may be filled or coated with a thermally insulating sealant (502) (e.g., rubber or silicone). This sealant suppresses lateral heat leakage, enhances water resistance, and protects against electrical short-circuiting between pellets in the presence of moisture. In addition to insulation, the sealant may be used to bond the modular stack to the garment, simplifying integration and increasing robustness.

If the modular multi-stage TEG design is used, heat is transferred among the TEG modules via a thermal interface material (202) positioned in between the thermal substrates (106) of each module. The modular embodiment may also incorporate external heat sinks or spreaders (503) thermally bonded to the outermost module substrates using TIM (202). Additional TIM is applied between the spreader surfaces and the module substrates to reduce contact resistance and ensure efficient heat transfer. This arrangement mirrors configurations where external spreaders enhance both heat absorption on the body side and heat rejection on the ambient side.

Together, the fixed and modular approaches enable control over the effective thermal resistance of the TEG (100). By tailoring the number of stages, substrate type, and thermal coupling, the TEG can be optimized to match garment-to-ambient heat paths, ensuring maximum electrical power extraction while maintaining flexibility and durability suitable for wearables. To achieve balanced operation in a multi-stage design, discrete thermoelectric modules with similar physical, thermal, and electrical characteristics are stacked.

The physical characteristics of each module include shape, thickness, area, and weight. Modules may be uniformly sized to ensure even heat flow across the stack. Lightweight modules are preferred to preserve garment comfort. Weight reduction may be achieved by reducing pellet size while maintaining the same length-to-cross-sectional ratio, or by thinning substrates and interface layers. Care must be taken, however, as reducing substrate or TIM area increases parasitic thermal resistance, which lowers power output.

The thermoelectric characteristics include the Seebeck coefficient of the material and the number of P-N pellet pairs (500) electrically connected in series. Materials such as bismuth telluride, doped to form P-type and N-type semiconductors, provide favorable performance near body temperature. Each pair produces a voltage proportional to the temperature difference across it; the stage output is the sum of all series-connected pairs. Consistency in material and pellet count across modules ensures balanced heat flow and voltage generation within the multi-stage stack.

The electrical characteristics include the resistance of the modules. If modules are physically and thermally similar, their electrical resistance should also be similar. The total resistance of each stage is the sum of its pellet-pair resistances. For system optimization, the TEG's total electrical resistance should be matched to the input impedance of the energy harvester.

The thermal characteristics include the resistance of each stage. To maintain uniform heat flow across the stack, the thermal resistances of the modules should be similar. The overall thermal resistance of a stage corresponds to the parallel resistances of its pellet pairs. To maximize electrical generation, the TEG's overall resistance is optimized against both the body-side and air-side resistances, while minimizing parasitic resistances introduced by substrates and TIMs.

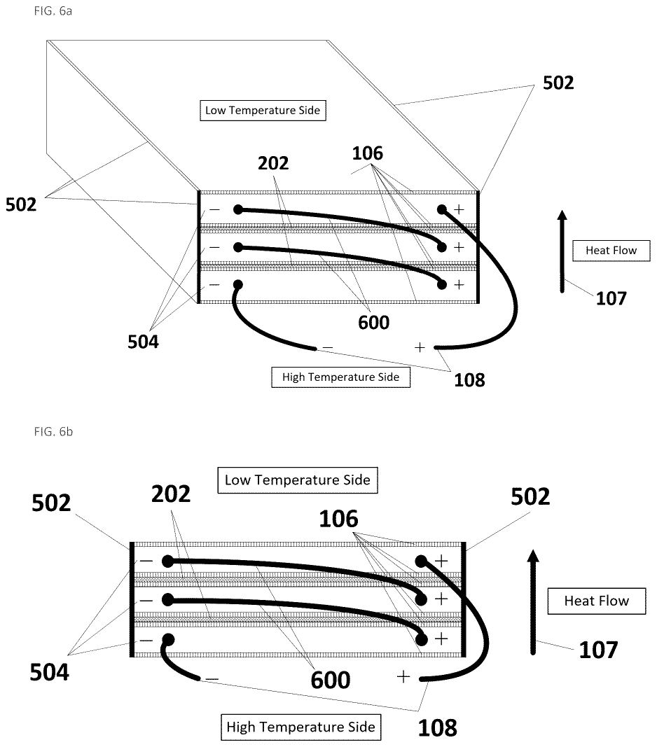

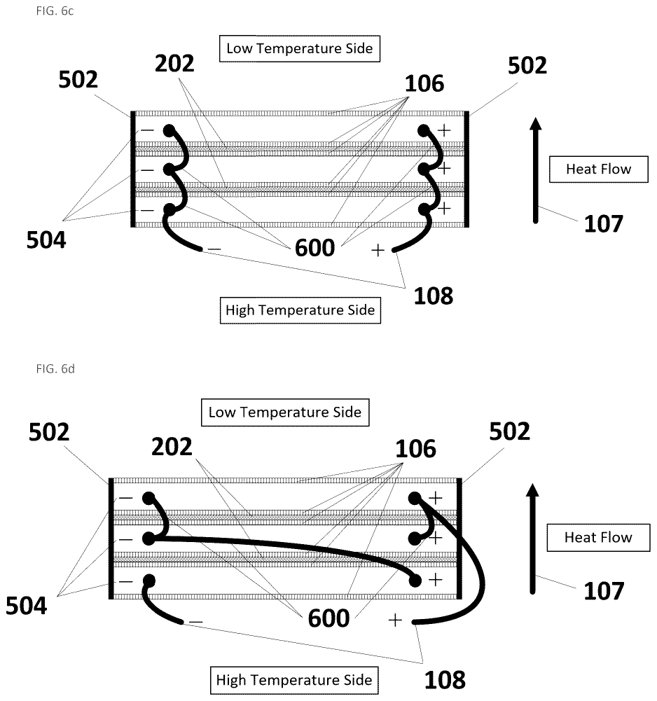

FIGS. 6a-6d illustrate the various electrical interconnection strategies for a modular multi-stage thermoelectric generator (TEG), demonstrating how the output voltage and internal electrical resistance of the TEG can be tuned without altering its thermal properties, which is used for impedance matching with the energy harvester circuit to achieve maximum power transfer.

FIG. 6a provides a three-dimensional perspective view of a modular multi-stage TEG stack, showing the physical arrangement of the individual TEG stages/modules (504) with their internal pellet structures (500) and thermal substrates (106). The modules are thermally coupled together with thermal interface material (202) disposed between adjacent module substrates to minimize inter-module thermal resistance. Thermally insulating sealant (502) is applied around the perimeter edges of the stack to suppress lateral heat leakage, improve water resistance, and bond the assembly together. The figure shows electrical interconnects (600) connecting the modules, with TEG output leads (108) emerging from the stack, marked with positive (+) and negative (−) terminals. Heat flow (107) is directed vertically from the high-temperature side (body heat source) toward the low-temperature side (ambient air). This three-dimensional view establishes the physical context for understanding the electrical interconnection schemes detailed in the subsequent figures, showing the modules as discrete stackable units available for various wiring configurations.

FIG. 6b illustrates a series electrical connection configuration in a cross-sectional view. In this arrangement, the positive terminal of one module is connected to the negative terminal of the adjacent module via electrical interconnects (600), linking all modules in a continuous electrical chain from the high-temperature side to the low-temperature side. The pellet structures (500) within each module are visible between the thermal substrates (106), with thermal interface material (202) coupling the modules thermally. The thermally insulating sealant (502) seals the edges of the stack on both sides. The series connection sums the voltage output of each individual stage, resulting in the highest possible total output voltage from the stack, which is delivered through the TEG output leads (108) marked with positive (+) and negative (−) terminals. However, this configuration also produces the highest total electrical resistance, as the internal resistances of each module are added together. Heat flow (107) continues to travel vertically through the stacked assembly from the high-temperature side to the low-temperature side.

FIG. 6c depicts a parallel electrical connection configuration. In this cross-sectional view, all the positive terminals of the modules are tied together through one set of electrical interconnects (600), and all the negative terminals are similarly connected together through another set, as shown by the curved interconnect paths linking the corresponding terminals on each side of the stack. The pellet structures (500), thermal substrates (106), thermal interface material (202), and thermally insulating sealant (502) maintain the same physical arrangement as in previous figures. This parallel configuration maintains the output voltage equal to that of a single module while minimizing the total electrical resistance of the TEG stack by effectively placing all module resistances in parallel. The combined output is carried through TEG output leads (108) marked with positive (+) and negative (−) terminals. This arrangement increases the current-carrying capacity and available output current for a given temperature differential, with heat flow (107) remaining vertically directed from the high-temperature side to the low-temperature side.

FIG. 6d illustrates a series/parallel combination or hybrid electrical connection configuration. This cross-sectional view shows a mixed topology where some stages are connected in series while others are connected in parallel, offering a balanced approach between the pure series and pure parallel configurations. The electrical interconnects (600) demonstrate this hybrid wiring scheme: the stage nearest the high-temperature side is connected in series with a parallel combination of two stages closer to the low-temperature side, as evidenced by the interconnect routing patterns. The pellet structures (500), thermal substrates (106), thermal interface material (202), and thermally insulating sealant (502) maintain their standard physical arrangement. The TEG output leads (108) with positive (+) and negative (−) terminals carry the combined electrical output. This hybrid configuration allows designers to fine-tune the TEG's electrical characteristics, creating an intermediate trade-off between output voltage and internal resistance that can be precisely matched to the dynamic input impedance requirements of the energy harvester circuit, while heat flow (107) continues its vertical path from the high-temperature side to the low-temperature side. Collectively, these four figures demonstrate that the electrical interconnection strategy can be selected independently of the thermal design, enabling optimization of power transfer efficiency across varying operating conditions while maintaining the same fundamental thermal stack-up and heat flow path through the modular multi-stage TEG assembly.

Together, these interconnection strategies provide the ability to tune the TEG's electrical performance for different system requirements, ensuring maximum energy extraction under varying operating conditions. By configuring modules in series, parallel, or hybrid combinations, the designer can tailor the TEG's electrical characteristics to the input impedance of the energy harvester circuit. Maximum power transfer occurs when the TEG's source resistance is approximately equal to the harvester's input impedance.

The electrical interconnection of thermoelectric modules directly influences the overall efficiency of the energy harvesting system. By selecting an appropriate series, parallel, or hybrid configuration, the total output voltage and internal resistance of the TEG (100) can be tuned to match the input impedance of the energy harvester circuit. This impedance matching, as maximum power transfer, occurs when the source resistance of the TEG equals the effective load presented by the harvester.

Series connection maximizes output voltage, which may be advantageous when operating ultra-low-voltage harvesters that require higher startup potential. However, series configurations also increase internal resistance, which may reduce current delivery efficiency if not properly matched to the harvester's design. Parallel connection, by contrast, minimizes resistance and increases current capacity, which is beneficial when the harvester can accept higher input currents at lower voltages. Hybrid series-parallel topologies provide additional flexibility, enabling the designer to balance voltage and resistance for optimal alignment with the harvester's dynamic operating point.

Efficiency is further enhanced by ensuring that modules used within the multi-stage TEG are electrically matched in terms of Seebeck coefficient, pellet count, and resistance. Mismatches between modules can cause uneven power distribution, resulting in localized inefficiencies and reduced net output. Uniform module design ensures consistent current sharing across parallel paths and balanced voltage contributions across series paths, which together maximize usable harvested energy.

Through careful selection of electrical interconnection schemes, the TEG's electrical output can be tailored to align with the harvester's impedance characteristics. This adaptability allows the wearable system to operate efficiently under a wide range of thermal gradients and environmental conditions, thereby improving both startup reliability and continuous power delivery for strobe-light operation. When combined with optimized thermal resistance strategies, these electrical configurations ensure that both thermal and electrical domains are jointly tuned for maximum overall efficiency in wearable applications.

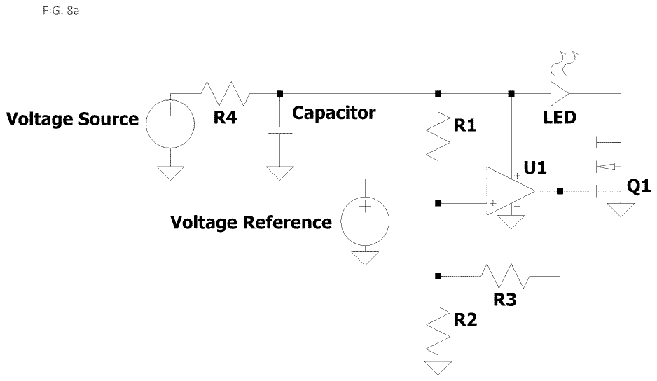

FIG. 7 illustrates a flowchart providing a high-level system architecture view of the simplified body-heat-powered strobe light, showing the electrical energy flow and functional relationships between the major subsystems. The diagram presents a left-to-right progression that traces the conversion of thermal energy into visible light through a series of interconnected functional blocks.

The system begins with the Thermoelectric Generator (100) block, which harnesses the temperature difference between the wearer's body heat and the ambient environment to produce electrical power. This TEG output power flows rightward via an arrow into the Energy Harvester Circuit block. The Energy Harvester Circuit serves as the power conditioning stage, extracting maximum available energy from the TEG's typically low voltage output and boosting it to a level usable by downstream electronics. This harvester employs impedance matching techniques to ensure efficient power transfer from the TEG (100), operating the generator near its maximum power point.

From the Energy Harvester Circuit, an arrow labeled “Charges energy storage device” directs the conditioned power into the Energy Storage Device (Capacitor Bank) block. This capacitor bank functions as the primary energy reservoir for the entire system, accumulating charge over time and providing both the instantaneous high-current pulses required by the lighting device and the operating power for the control circuitry. The capacitor bank serves a dual role: it buffers the relatively low continuous current output of the energy harvester and enables the delivery of short, bright strobe flashes that would otherwise exceed the harvester's instantaneous current capability.

The “Power to lighting device,” path represents the high-current discharge pulses that illuminate the LED (110) during each strobe cycle. The “Power and charge level information to oscillator and driver circuit,” extends downward and then rightward to the Combined Oscillator and Driver Circuit block positioned in the lower right. The block is further annotated as “(A stable multi-vibrator Comparator and power transistor),” indicating its implementation as a simple, efficient oscillator circuit that uses a comparator with hysteresis and a switching transistor.

The Combined Oscillator and Driver Circuit block receives both operating power and voltage state information from the capacitor bank. In this simplified embodiment, the capacitor bank itself functions as the timing element of the oscillator. The comparator within this circuit continuously monitors the capacitor voltage against upper and lower threshold levels established by its hysteresis network. When the capacitor voltage reaches the upper threshold, the comparator switches state and activates the power transistor, allowing current to flow through the LED (110). As the LED draws current, the capacitor discharges until its voltage falls to the lower threshold, at which point the comparator deactivates the transistor and the LED turns off. The capacitor then recharges from the energy harvester, and the cycle repeats automatically.

“Driver circuit turns on/off lighting device,” connects the Combined Oscillator and Driver Circuit block upward to the Lighting Device (LED) (110) block, closing the control loop. This signal path represents the switching action that controls the LED's on/off state, producing the characteristic strobe effect. The frequency of this strobing is inherently determined by the rate at which the energy harvester can charge the capacitor bank and the hysteresis thresholds of the comparator-faster charging results in higher strobe frequency, while slower charging produces a lower frequency. This self-regulating behavior allows the system to automatically adapt its strobe rate to the available body heat, maintaining visibility across varying environmental conditions without requiring active control circuitry.

The overall architecture consolidates multiple functions into minimal components. The energy storage capacitor serves simultaneously as both the power reservoir and the timing element, eliminating the need for separate oscillator timing components. The combined oscillator and driver circuit handles both frequency generation and power switching in a single stage, minimizing quiescent power consumption. This integrated approach ensures that nearly all harvested energy is directed toward producing visible light, making the system practical for body-heat-powered wearable applications where available power is inherently limited.

Wires or cables (108) connect the TEG's electrical output to the electronic circuit board (109). The electronic circuit board contains all the electronics necessary to harvest the TEG's electrical power, condition the voltage to be used for a lighting device, power and strobe the lighting device, and contain the lighting device, such as an LED (110).

The system first extracts electrical energy generated by the thermoelectric generator (TEG) (100) using an energy harvester circuit. The energy harvester, implemented as a voltage converter, is configured to increase the TEG's low output voltage to a level sufficient to operate the oscillator, driver, and lighting circuits. Because a TEG delivers maximum output power when its internal resistance equals the load resistance and its terminal voltage is approximately half of its open-circuit voltage, the energy harvester is designed to match its input impedance to the TEG's internal resistance.

This impedance matching may be achieved through either passive or active methods. In passive systems, the input impedance of the harvester varies naturally with input power: increasing when the available input power decreases and decreasing as the input power increases. A resonant step-up converter is an example of such a passive impedance-matching energy harvester.

In active systems, maximum power point tracking (MPPT) control is employed. The harvester regulates its input voltage and current relative to a reference voltage in order to maintain effective impedance matching. When the TEG voltage is below the reference, the harvester reduces input current; when the voltage is above the reference, input current is increased. This control may be implemented using analog circuitry, digital circuitry, or a combination thereof. A DC-DC boost converter with input voltage regulation provides one example of active control.

The reference voltage may be fixed or dynamic. In a fixed-reference approach, the harvester maintains the input voltage at a constant value, typically set to one-half of the TEG's open-circuit voltage. In a dynamic-reference approach, such as the fractional open-circuit voltage method, the harvester periodically measures the TEG's open-circuit voltage and updates the reference accordingly. This ensures that the harvester continuously adjusts its input impedance to match the TEG's internal resistance, regardless of changes in the TEG's output voltage or the temperature differential across it. This provides a more robust approach for a body-heat-powered wearable strobe light, where environmental conditions are dynamic and subject to change.

### Energy Storage and Power Distribution

When electrical power is harvested from the thermoelectric generator (TEG) (100) using an energy harvesting circuit, the harvested power is directed into an energy storage device, such as a capacitor bank. The capacitor bank functions as the primary power source for the strobe lighting device (110) and its associated oscillator and driver circuits. This arrangement allows the strobe circuit to draw high instantaneous current from the capacitor bank, rather than directly from the energy harvester.

In operation, the energy harvester typically provides only tens of microamperes to a few milliamperes of continuous current, depending on the temperature differential across the TEG (100). By contrast, the strobe lighting device (110) requires short bursts of current on the order of tens to hundreds of milliamperes. The capacitor bank enables this by accumulating charge over longer time intervals and discharging rapidly during each strobe event.

This storage-and-discharge method ensures that the lighting device produces bright and consistent light pulses, while allowing the harvester to operate efficiently at its optimal current output. By prioritizing the gradual charging of the capacitor bank before each pulse, the system maximizes usable energy per strobe, thereby improving both power delivery to the lighting device and overall visibility performance. This energy-buffering arrangement not only enables the lighting device to achieve high instantaneous brightness but also establishes a stable supply for the oscillator and driver circuits, which regulate the timing and duty cycle of the strobe pulses.

In advanced embodiments, the system incorporates a power management and energy storage circuit that manages charging of the energy storage element (e.g., a capacitor bank) and distributes power to downstream circuits. From the power management circuit, energy is supplied both directly and through a voltage regulator. The voltage regulator may provide a stable supply rail to sensitive circuits, such as the oscillator or microcontroller, while allowing other circuits and lighting devices to draw unregulated power for efficiency, or through an optional voltage regulator. The inclusion of the voltage regulator enables compatibility with a wider range of driver and control circuits.

Two types of voltage regulators may be employed. A first regulator is dedicated to the low-power control domain, supplying the oscillator, clock, or microcontroller with a stable rail. Because it only supports ultra-low-power circuitry, its quiescent draw is negligible relative to LED current demand. An optional second regulator may be included in the power domain to provide consistent supply voltage to the driver circuit and lighting devices (110). This optional regulator may improve brightness uniformity and driver reliability under fluctuating input power, but can be omitted to reduce losses when direct operation from the storage capacitor is preferred.

### Strobe Light Circuit Design and Control

The strobe light circuit is configured to efficiently control and drive a lighting device (110), preferably a light-emitting diode (LED), due to its high luminous efficacy, low power consumption, and bright output. The LED is selected as the primary lighting element because it produces bright, focused illumination with minimal energy input—an essential feature in body-heat-powered applications. By pulsing the LED at regular intervals, the circuit conserves harvested energy while maintaining high visibility. The capacitor bank, continuously charged by the energy harvester or storage element, delivers the instantaneous current required for each flash. This arrangement ensures that the strobe remains bright and consistent even under fluctuating input power, thereby maximizing both reliability and visibility in wearable conditions.

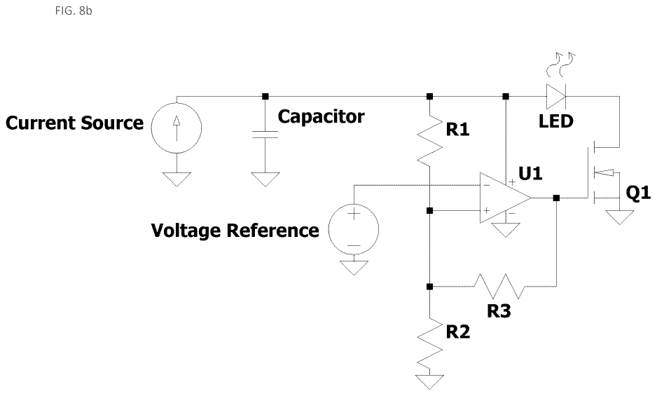

FIGS. 8a and 8b illustrate two embodiments of a basic strobe light circuit implementing an astable multivibrator configuration, demonstrating how the strobe frequency is determined by the charging characteristics of the capacitor bank and controlled by a comparator-based oscillator with hysteresis. Both circuits share the same fundamental topology but differ in their power source implementation, with FIG. 8a powered by a voltage source and FIG. 8b powered by a current source.

FIG. 8a depicts the voltage source embodiment of the strobe light circuit. On the left side of the schematic, a Voltage Source is shown with its positive terminal at the top and negative terminal (ground) at the bottom, represented by the standard ground symbol. The voltage source connects through a series resistor R4, which represents either an external current-limiting resistor or the internal source resistance of the voltage supply. This series resistance R4 establishes the RC charging time constant that governs the capacitor charging rate. The resistor R4 connects to the positive plate of the Capacitor (the capacitor bank or energy storage element), which is represented by the standard capacitor symbol with one solid line (representing the top plate) and one hollow line (representing the bottom plate connected to ground). The capacitor's negative plate connects to ground, forming the primary energy storage element of the circuit.

The capacitor's positive terminal also connects to three parallel circuit branches that form the heart of the oscillator and driver circuitry. The first branch contains resistor R1, which connects from the capacitor positive terminal to a node that feeds into the non-inverting positive input terminal of comparator U1. The comparator U1 is depicted as a triangular operational amplifier symbol with the positive input on the top, the negative input on the bottom, and the output emerging from the right apex of the triangle. The comparator's negative (inverting) input connects to the Voltage Reference, which provides a stable reference voltage against which the capacitor voltage is compared. The voltage reference is shown as a circular symbol with positive and negative terminals, with its negative terminal connected to ground.

The second branch from the capacitor positive terminal leads through resistor R2, which connects downward to ground. Together with resistor R3 (described below), resistors R1 and R2 form a voltage divider network that establishes the hysteresis thresholds of the comparator. This hysteresis is essential for creating the astable multivibrator behavior, ensuring that the comparator switches cleanly between states and defining the upper and lower voltage thresholds at which the LED turns on and off.

The output of comparator U1 connects to the gate terminal of N-channel MOSFET Q1, shown on the right side of the schematic as a standard MOSFET symbol with source, drain, and gate terminals. The MOSFET Q1 functions as an electronic switch that controls current flow through the LED (110). The drain terminal of Q1 connects through the LED (depicted with the standard diode symbol with arrows indicating light emission) to the capacitor positive terminal, while the source terminal of Q1 connects to ground. When the comparator output is high, the MOSFET gate is driven to turn on the transistor, allowing current to flow from the capacitor through the LED and through the MOSFET's drain-source channel to ground, thereby illuminating the LED (110).

The third branch involves feedback resistor R3, which connects from the comparator output back to the comparator's non-inverting positive input, joining at the same node where R1 terminates. This feedback resistor R3 is the key element that establishes positive feedback and creates the hysteresis characteristic of the Schmitt trigger oscillator. When the comparator output switches high, resistor R3 feeds a portion of that high voltage back to the positive input, raising the threshold voltage that must be overcome to switch the comparator back to its low state. Conversely, when the output is low, the feedback through R3 lowers the effective threshold. This creates two distinct switching thresholds—an upper threshold for turning the LED (110) on and a lower threshold for turning it off—that define the charge and discharge voltage window of the capacitor.

In operation, the voltage source charges the capacitor through resistor R4 with an exponential charging characteristic determined by the RC time constant (R4 multiplied by the capacitance value). As the capacitor voltage rises, it is monitored by the comparator U1 through the resistive network R1, R2, and R3. When the capacitor voltage reaches the upper hysteresis threshold established by the voltage reference and the feedback network, the comparator output switches high, turning on MOSFET Q1. With Q1 conducting, current flows from the capacitor through the LED (110) to ground, causing the LED (110) to illuminate while simultaneously discharging the capacitor. The capacitor voltage then falls until it reaches the lower hysteresis threshold, at which point the comparator output switches low, turning off Q1 and the LED (110). The cycle then repeats as the voltage source recharges the capacitor through R4. The strobe frequency is thus determined by the charging time constant (governed by R4 and the capacitor value), the discharge time (governed by the LED forward voltage, capacitor value, and LED current), and the voltage spacing between the upper and lower hysteresis thresholds (set by R1, R2, R3, and the voltage reference).

FIG. 8b depicts the current source embodiment of the strobe light circuit. This schematic is nearly identical to FIG. 8a, with the difference being that the voltage source and series resistor R4 from FIG. 8a are replaced by a Current Source on the left side of the diagram. The current source is represented by a circle containing an upward-pointing arrow, indicating a constant current flow direction, with its negative terminal connected to ground. Unlike the voltage source configuration, the current source provides a constant current to charge the capacitor, resulting in a linear charging characteristic rather than the exponential RC charging of the voltage source embodiment.

All other circuit elements remain functionally identical to FIG. 8a. The current source connects directly to the positive plate of the Capacitor, which serves as the energy storage element with its negative plate grounded. The capacitor's positive terminal again branches into three paths: through resistor R1 to the positive (non-inverting) input of comparator U1, through resistor R2 to ground (forming part of the voltage divider and hysteresis network), and through the LED (110) and MOSFET Q1 to ground when Q1 is switched on. The Voltage Reference connects to the negative (inverting) input of comparator U1, providing the comparison threshold. Feedback resistor R3 connects from the comparator output back to the positive input at the junction with R1, establishing the hysteresis behavior. The comparator U1 output drives the gate of N-channel MOSFET Q1, which switches the LED (110) on and off. The LED's (110) anode connects to the capacitor positive terminal, and its cathode connects to the drain of Q1, with Q1's source grounded.

In this current source configuration, the capacitor charges linearly over time according to the relationship V=(I×t)/C, where I is the constant charging current, t is time, and C is the capacitance. This linear charging contrasts with the exponential charging of the voltage source embodiment and can provide more predictable timing characteristics. When the capacitor voltage reaches the upper hysteresis threshold, the comparator switches high, activating Q1 and allowing the capacitor to discharge through the LED (110). The LED (110) remains on, discharging the capacitor, until the voltage falls to the lower hysteresis threshold, at which point the comparator switches low, deactivating Q1. The current source then resumes charging the capacitor linearly, and the cycle repeats. The strobe frequency in this embodiment is determined by the charging current magnitude, the capacitance value, the LED discharge characteristics, and the hysteresis threshold spacing.

Both FIGS. 8a and 8b demonstrate the fundamental principle of the simplified strobe light system: the same capacitor that stores harvested energy and powers the LED (110) also serves as the timing element for the oscillator. The comparator with hysteresis (U1, R1, R2, R3) functions simultaneously as both the oscillator that generates the strobe timing and the voltage regulator that controls the capacitor bank voltage, thereby minimizing component count and maximizing efficiency. In a practical body-heat-powered implementation, the voltage or current source would be provided by the energy harvester circuit connected to the thermoelectric generator (100), with the source characteristics reflecting the available thermal energy. When body heat is abundant, the source provides higher voltage or current, the capacitor charges more quickly, and the strobe frequency increases automatically. When the thermal gradient is reduced, charging slows and frequency decreases naturally, creating a self-regulating system that adapts to available power without requiring active control circuitry. This elegant dual-use architecture ensures that nearly all harvested energy is directed toward producing visible light, making these circuits highly suitable for energy-constrained wearable applications.

The circuit includes a lighting device (110), an oscillator or clock, a driver circuit, and an energy storage element such as a capacitor bank. In simplified embodiments, the oscillator and driver may be implemented as a simple astable multivibrator utilizing a low-power comparator with hysteresis to drive a power transistor.

In this configuration, the comparator's hysteresis explicitly governs when the lighting device (110) should turn on and off, based on the voltage of the capacitor bank. The comparator compares the capacitor bank voltage to its reference voltage: once the voltage reaches the upper threshold, the comparator enables the transistor to power the lighting device (110). The LED (110) discharges the capacitor until its voltage falls to the lower hysteresis threshold, at which point the device switches off. The cycle then repeats as the capacitor recharges, creating a self-sustaining oscillation. This hysteresis-controlled charge-discharge cycle not only produces the strobe effect but also regulates the capacitor bank voltage, thereby setting the operating voltage and brightness of the lighting device (110).

The strobe light circuit provides a compact and efficient design in which the strobe frequency is determined by the charge rate of the capacitor bank. The circuit employs an astable multivibrator, which may be a type of Schmitt trigger oscillator, configured to generate a periodic pulsed signal that drives the LED (110), thereby creating the strobing effect. The combination of a comparator/op-amp, hysteresis resistor network, capacitor bank, reference voltage, and MOSFET switch enables reliable and energy-efficient operation of the LED (110) with minimal component count.

FIG. 9 illustrates a high-level architectural flowchart of an advanced embodiment for the body-heat-powered strobe light, representing a significant evolution from the simplified system of FIG. 7. This enhanced configuration introduces dedicated power management, voltage regulation, and modular driver circuits to achieve superior energy regulation, control stability, and operational adaptability under the variable output conditions of a thermoelectric generator (TEG) (100). The diagram delineates a clear separation between power and control domains, interconnected through a central power management hub.

The system originates with the Thermoelectric Generator (TEG) (100), which converts the temperature differential between the wearer's body and the ambient environment into electrical power. This raw output is delivered via TEG output leads (108) to the Energy Harvester Circuit, which performs power conditioning by extracting maximum available energy through impedance-matching techniques and boosting the TEG's (100) low voltage to a usable level for subsequent electronics.

The conditioned power is then managed by the Power Management and Energy Storage Circuit, which serves as the central nexus of the system. This subsystem represents a key advancement, actively managing the charging of an energy storage element (such as a capacitor bank) and intelligently distributing power through multiple independent output paths to serve different circuit domains with their specific voltage and current requirements.

From this central hub, power is distributed along several distinct pathways. One path supplies an optional Voltage Regulator dedicated to the lighting devices (110), which can be included to ensure consistent LED brightness or bypassed for maximum efficiency. This regulator feeds the Lighting Devices (LEDs) (110) block, which comprises one or more light-emitting diodes, enabling multi-LED configurations for distributed illumination. A separate, unregulated power path connects directly from the Power Management circuit to the LEDs (110), providing a high-efficiency alternative.

The Driver Circuits block, which contains comparator/operational amplifier and power transistor pairs, receives its operating power directly from the Power Management hub. These modular circuits are responsible for switching the LEDs (110) on and off. Their operation is governed by control signals received from the Oscillator/Clock block, which can be implemented as an analog circuit (e.g., a Schmitt trigger oscillator) or a low-power microcontroller for programmable timing. This separation of the timing generation from the energy storage element is a fundamental architectural shift, enabling stable, predictable strobe frequency independent of harvesting dynamics.

The Oscillator/Clock is powered by a dedicated Voltage Regulator, which itself is supplied by the Power Management circuit. This arrangement provides a clean, stable supply rail to the sensitive control circuitry, ensuring consistent timing generation immune to fluctuations in the main storage capacitor's voltage.

This advanced architecture delivers several key advantages. It decouples strobe frequency from the energy harvesting rate, ensuring consistent flash timing. The modular driver design supports multi-LED operations, such as sequential activation or phase-shifted strobing, which concentrates available energy into brighter individual pulses. The system can dynamically manage its power budget, adapting to changing thermal conditions by adjusting the number of active LEDs or their drive parameters. Ultimately, this design provides a flexible, stable, and highly controllable platform for advanced wearable strobe light applications, building upon the foundational efficiency of the simplified system with enhanced performance and feature sets.

Integration with Thermoelectric Power Source

In a practical embodiment, the voltage or current source supplying the capacitor bank may be derived from a thermoelectric generator (TEG) (100) coupled with an energy harvester circuit. The TEG (100) behaves as a Thevenin source, producing an open-circuit voltage with an internal resistance, while the energy harvester functions as a voltage converter that conditions this output. Depending on configuration, the harvester may act effectively as a voltage source with series resistance or as a current-limited source.

In either case, the charging characteristics of the capacitor bank directly reflect the available thermal energy: when body heat and ambient temperature differentials are high, the source voltage or current increases, the capacitor charges more quickly, and the strobe frequency rises; when the differential is small, the charging rate slows and the frequency decreases. Regardless of these variations, the comparator with hysteresis maintains consistent switching thresholds, ensuring that each LED (110) pulse is delivered with stable brightness. This embodiment demonstrates how the circuit adapts naturally to fluctuating TEG (100) output conditions, providing reliable and efficient strobing operation in wearable body-heat-powered applications.

### Adaptive Frequency and Self-Regulation

This simplified system is inherently efficient because the same hysteresis comparator that generates the strobing signal also regulates the voltage of the capacitor bank, eliminating the need for a separate power management stage. Likewise, the capacitor bank serves a dual role: it functions both as the primary reservoir of harvested energy and as the timing element of the oscillator, reducing component count and quiescent losses.

The strobe frequency scales naturally with the rate of harvested energy. Under low body-to-ambient temperature differentials, the capacitor charges slowly, producing a lower strobe frequency. At higher gradients, faster charging results in more frequent pulses. This self-adjusting behavior ensures that the device always operates within the available energy budget without requiring active monitoring circuitry.

In practical operation, the system may be designed for a minimum strobe frequency—e.g., 2 Hz—under the lowest expected temperature gradients. At higher gradients, flash frequency increases automatically, ensuring visibility even in constrained power conditions while maximizing attention-grabbing capacity when more energy is available.

The strobe frequency and duty cycle can be tailored by adjusting resistor and capacitor values within the oscillator circuit, or by modifying the capacitor charge rate through changes in source voltage or current. A higher charge rate increases frequency, while a lower rate decreases it. By controlling the capacitor's charge-discharge cycle between two defined thresholds, the circuit achieves both frequency regulation and brightness stability. This configuration maintains consistent strobe operation under varying TEG (100) output power while remaining compact, energy-efficient, and well suited for wearable applications requiring reliable visibility. These design choices reduce wasted power, maximize energy conversion, and enable a naturally adaptive strobe frequency.

### Advanced Oscillator and Driver Architecture

In the simplified embodiment, the oscillator and driver circuit are directly coupled to the primary energy storage capacitor and the lighting device (110). In this configuration, the same capacitor that powers the lighting device (110) also defines the timing cycle, such that the charge and discharge of the capacitor determine both the strobe frequency and the light output. As a result, the frequency of operation is inherently linked to the rate at which energy is harvested and stored.

In the advanced embodiment, control of the lighting device (110) is achieved by separate oscillator/clock circuits and driver circuits. The oscillator/clock may be implemented as an analog circuit (such as a comparator-based astable multivibrator, that may be a Schmitt trigger oscillator with a dedicated timing capacitor, or timer circuit) or as a microcontroller configured to generate timing signals. The oscillator delivers control signals to one or more driver circuits.

In the advanced embodiment, the oscillator may instead be implemented as an independent timing circuit, such as a Schmitt trigger oscillator with a dedicated timing capacitor, that is electrically uncoupled from the main energy storage device, which may be a capacitor bank. In this configuration, the oscillator establishes the strobe frequency using a dedicated timing capacitor and hysteresis network, independent of the voltage across the main energy storage capacitor.

The energy storage capacitor is used primarily as a power reservoir to provide the instantaneous current required to drive the lighting device (110), while the oscillator circuit-supplied through the power management and voltage regulation subsystem-generates stable timing signals regardless of the charging dynamics of the storage capacitor. This separation enables the advanced system to maintain a consistent strobe frequency under varying thermoelectric generator (100) output conditions, while still delivering sufficient instantaneous current to the lighting device (110). It also provides additional functionality, such as sequential LED activation and adaptive brightness control, which are not practical when the oscillator timing is directly tied to the voltage of the primary energy storage capacitor.

Each driver circuit may include a comparator or operational amplifier combined with a power transistor, such as an N-channel MOSFET, for switching a lighting device (110). The driver circuits, in turn, regulate the on/off operation of one or more lighting devices (110), preferably light-emitting diodes (LEDs). In this configuration, the system allows for multiple LEDs (110) to be driven independently or in groups, with each driver circuit receiving timing input from the oscillator while drawing stored energy from the power management circuit.

The oscillator generates the strobe frequency and may be implemented digitally with a microcontroller or as an analog circuit, including but not limited to an astable multivibrator, crystal oscillator, or other timing configuration. The driver circuit may comprise a comparator or operational amplifier (op-amp) and an electronic switch, such as an N-channel or P-channel MOSFET, to regulate current flow through the LED (110).

At each clock cycle, the oscillator produces a pulse signal with a defined duty cycle. This signal is processed by the comparator or op-amp into a drive waveform that switches the MOSFET, thereby powering the LED (110) with minimal loss. The MOSFET turns off when the pulse ends, producing a repeating strobe effect. The capacitor bank stores energy harvested from the source and discharges during each LED (110) pulse, supplying short bursts of high current that the harvester alone cannot provide.

By incorporating dedicated power management, voltage regulation, and modular driver circuits, the advanced system provides improved control, and greater flexibility compared to the basic embodiment. This design enables more precise frequency and brightness regulation, supports multiple lighting devices (110), and ensures stable operation under dynamic environmental conditions where TEG (100) output may fluctuate.

### Multi-LED Configurations and Sequential Operation

Unlike simplified configurations which support a single LED (110) in minimal design, advanced embodiments anticipate multiple LEDs (110) controlled with more complex driver circuitry. This enables distributed illumination and more strobing sequences. The system allows for multiple LEDs (110) to be driven independently or in groups. One or more light-emitting diodes (110) may be configured for high-efficiency illumination in a strobe pattern, which may be operated independently or in groups.

In certain implementations, the advanced body-heat-powered strobe light system may maximize the effective brightness of the lighting devices (110) by controlling them sequentially rather than simultaneously. For example, where multiple LEDs (110) are provided, the system may energize a first LED (110) for one strobe cycle, then allow a brief off-time for capacitor recharge before energizing a second LED (110), and so forth. This sequential operation ensures that the available energy stored in the capacitor bank is concentrated into a single LED (110) at a time, thereby increasing the instantaneous brightness of each pulse without requiring higher continuous power from the thermoelectric generator (100).

This functionality may be achieved by configuring the oscillator to provide phase-shifted control signals to the driver circuits, or by programming a microcontroller to address the driver circuits in sequence. In an analog implementation, multiple astable multivibrator stages, that may be Schmitt trigger oscillators, may be cascaded or configured with phase offsets, each stage controlling a separate driver circuit and corresponding LED (110). In another more stable analog implementation, a single central oscillator may be used to control a cascade of flip-flops, such as D flip-flops, with each flip-flop output controlling a separate driver circuit. In this configuration, the central oscillator frequency is divided by the number of flip-flops for each driver circuit. This creates a phase offset behavior for the driver circuits, from the central oscillator frequency. In a digital implementation, a microcontroller may generate non-overlapping timing signals such that only one LED (110) is activated during each strobe period.

By tuning the duty cycle, off-time, and sequencing of the LEDs (110), the system can adaptively balance capacitor recharge time with output brightness. This approach provides a means of maximizing visibility and extending operational time under limited power conditions. Additionally, the system may dynamically adjust the number of active LEDs (110) depending on the amount of energy available, further enhancing adaptability to changing environmental and thermal conditions.

In alternative implementations, the oscillator may be configured to adaptively vary its frequency based on the energy available in the storage element, thereby reintroducing an adaptive frequency feature similar to that of the simplified embodiment. This may be achieved through sensing circuitry, programmable logic, or biasing arrangements that adjust the charging characteristics of the timing capacitor in response to the storage capacitor voltage.

Such an approach combines the advantages of stable operation with the ability to modulate strobe frequency according to available body-heat power, enhancing both efficiency and visibility under dynamic thermal conditions.

### Circuit-Level Efficiency Optimization

The circuit configuration is highly efficient in body-heat-powered applications where available energy is extremely limited. The lighting device (110) is preferably a light-emitting diode (LED), selected for its high luminous efficacy and low forward current requirement. The switching element is an N-channel MOSFET having low gate charge, low gate threshold voltage, and low on-resistance, thereby minimizing both switching and conduction losses. The comparator forming the Schmitt trigger oscillator is selected from ultra-low-power devices whose quiescent consumption is negligible relative to the LED (110) current demand.

A further efficiency advantage of the simplified configuration is that the energy storage capacitor simultaneously serves as both the primary power reservoir and the timing element of the oscillator. This dual use eliminates redundant components, ensuring that nearly all harvested energy is directed toward producing visible light.

In addition, because the capacitor's charge rate depends on the harvested input current, the strobe frequency naturally scales with the available thermal gradient-slower under low-power conditions and faster when more heat is available. This self-adjusting behavior maintains visibility across a wide range of environments without requiring active regulation.

Building on the system-level efficiency of simplified embodiments and the circuit-level component optimization, the advanced embodiment is designed for high efficiency while maintaining stable operation, scalability, independent timing control, and refined power management. In this configuration, the oscillator may be implemented as an independent Schmitt trigger circuit with a dedicated timing capacitor, electrically uncoupled from the main energy storage device.

By separating the timing function from the storage function, the oscillator operates on a regulated low-power rail and maintains consistent frequency control regardless of the charging dynamics of the storage capacitor. This prevents frequency drift that could otherwise occur due to variations in harvested energy, thereby ensuring predictable and efficient operation. The energy storage device, typically a capacitor bank, is reserved exclusively for providing instantaneous current to the lighting devices (110). Because the oscillator does not share this capacitor for timing, the storage capacitor's charge and discharge can be optimized purely for LED (110) power delivery. This reduces perturbations in the oscillator loop and ensures that nearly all stored charge contributes directly to visible light pulses.

Driver circuits employ low-gate-charge MOSFETs with low gate threshold voltage and low on-resistance to minimize both switching and conduction losses. Multiple driver circuits may be implemented, each controlling a separate LED (110), and may be sequenced or phase-shifted to activate only one LED (110) at a time. This method concentrates available energy into individual pulses, thereby increasing peak brightness while allowing recovery intervals for the storage capacitor. The result is higher luminous efficacy and extended runtime under limited power conditions.

LEDs (110) remain the preferred lighting elements due to their high luminous efficacy and low forward current requirements. Together, these design choices reduce wasted power, maximize energy conversion, and enable naturally adaptive or stable strobe frequency. In combination, these features maximize conversion of harvested thermal energy into visible light output, while providing stable strobe frequency, adaptability to changing thermoelectric generator (100) output conditions, and scalability to multi-LED configurations.

### Aquatic and Specialized Applications

The body-heat powered strobe light clothing system may also be applied to aquatic activities, including but not limited to swimming, scuba diving, and other underwater or wet environments where visibility is reduced. The layered construction of the clothing, combined with integrated rubber sealants and thermal pathways, provides both waterproofing and mechanical protection for the embedded electronics. This ensures that the thermoelectric generator (100), circuit boards (109, 203), and lighting devices (110) remain functional even under prolonged water exposure.

The multi-layer fabric design may further incorporate adhesives (103, 104) and sealants to provide water resistance and mechanical flexibility, while maintaining strong bonds between the TEG (100), spreaders (200, 201), and fabric layers (101, 102). The clothing is adaptable across garments including shirts, jackets, vests, socks, wristbands, headbands, harnesses, and helmets, enabling versatile use for humans or animals.

Rubber sealant (103, 111) serves a dual role: securing the TEG (100) to the garment and providing both water resistance and mechanical reinforcement. By also coating the circuit boards (109, 203), the sealant (111) allows the system to maintain long-term reliability without bulky enclosures (301) or protective cases. This not only preserves energy by reducing thermal barriers but also improves durability under sweat, moisture, and impact.

Unlike battery-powered strobes, which may present risks such as leakage, corrosion, or catastrophic failure when immersed, the present system eliminates reliance on electrochemical storage cells. By deriving all operating power directly from the wearer's body heat through the thermoelectric generator (100), the system avoids safety hazards associated with batteries in aquatic environments, including potential explosive/fire burns or chemical exposure risks. The design thereby improves both safety and reliability for the wearer in conditions where traditional battery-powered lighting devices may be compromised.

Furthermore, because the system continually operates as long as a temperature gradient exists across the thermoelectric generator (100), the strobe light maintains functionality without requiring replacement or recharging of a battery. This continuous, body-heat-driven operation enhances safety in low-visibility aquatic environments by ensuring consistent illumination whenever the garment is worn.

The body-heat powered strobe light system may be adapted for a wide range of safety, recreational, and professional contexts. Across all use cases, the self-powered architecture provides visibility without reliance on disposable or rechargeable batteries, ensuring continuous operation whenever a sufficient body-to-ambient temperature differential exists.

Individuals engaged in jogging, cycling, walking, or other outdoor activities during dusk or nighttime may wear garments or accessories integrating the strobe system. The strobe provides continuous visibility to motorists and other pedestrians, improving safety without requiring the user to monitor or recharge batteries.

The invention may be integrated into swimming attire, wetsuits, dive gear, or buoyancy vests. Waterproof sealing of the TEG (100) and electronics (105, 109, 203) ensures functionality during immersion, making the system well-suited for swimmers, divers, and rescue personnel operating in low-visibility or open-water conditions. Unlike battery-based lights, the system avoids catastrophic failures including potential explosive/fire burns or chemical leakage risks and maintains consistent operation throughout water exposure.

The system may be incorporated into work vests, helmets, or harnesses for construction workers, road crews, utility personnel, or first responders. The continuous strobe function provides high visibility in hazardous or poorly lit environments. In ruggedized embodiments, reinforced TEG modules (100), flexible substrates (106), and protective encapsulants (111) ensure reliability under dust, impact, or mechanical stress.

Collars, harnesses (400), or wearable accessories for pets, livestock, or service animals may embed the system to provide visibility at night. The strobe may enhance both safety in traffic environments and monitoring in open fields or during search-and-rescue operations.

The system may be deployed in survival clothing, life vests, or headgear for stranded individuals, lost hikers, or disaster survivors. Because no external power is required, the system provides continuous signaling capability for extended periods without maintenance.

Outdoor enthusiasts, such as campers, climbers, or mountaineers, may use garments incorporating the system for safety and signaling. Specialty versions may integrate colored LEDs (110) or patterned strobes to distinguish group members or signal specific conditions in recreational or tactical contexts.

### Alternative Embodiments and Design Variations

In alternative embodiments, the invention may be realized using a variety of structural, material, and circuit-level modifications, while still maintaining its core functionality of harvesting body heat to power a wearable strobe light.

The TEG (100) may be implemented as a single-stage device, a fixed multi-stage device, or a modular multi-stage stack (504). In certain embodiments, the TEG (100) employs rigid ceramic substrates (106) such as alumina or aluminum nitride; in others, flexible thermal substrates (106) such as polyimide films, coated metallic foils, or composite laminates may be used to improve mechanical compliance and wearer comfort. Edge sealing may be accomplished with thermally insulating adhesives (502) (rubber, silicone, or equivalent), while in other embodiments thermally conductive adhesives are applied in place of, or in combination with, discrete thermal interface materials (202).

In some implementations, no heat sinks or spreaders are employed, resulting in a compact and lightweight garment-integrated device. In alternative designs, rigid or flexible spreaders (200, 201, 503) are attached to one or both sides of the TEG (100) to improve heat collection and dissipation. Spreader materials (200, 201, 503) may include copper, aluminum, graphite, or advanced composites. In further embodiments, spreaders (200, 201, 503) may also serve as protective housings or structural reinforcements for fragile thermoelectric modules (100).

The energy storage element may comprise a single capacitor, a capacitor bank, or in some embodiments a rechargeable thin-film or solid-state battery. Regulation may be omitted in simplified systems, or included in more advanced configurations where constant voltage to the LED(s) (110) is desirable. Multiple regulators may be employed, with one dedicated to low-power oscillator and control circuitry, and another optional regulator stabilizing the LED (110) supply.

The strobe oscillator may be realized with a simple hysteretic comparator forming an astable multivibrator, or through a microcontroller, FPGA, or programmable logic device. In one embodiment, the oscillator frequency varies adaptively with available harvested power, while in another it is stabilized by decoupling the timing capacitor from the main storage capacitor. Driver circuits may employ MOSFETs, BJTs, or integrated driver ICs, selected for low on-resistance and low quiescent consumption.

The lighting device (110) may be a single LED, multiple LEDs (205), or an array arranged for distributed illumination. Multiple LEDs (110, 205) may be activated simultaneously, in sequence, or in phase-shifted strobing patterns to improve visibility while managing limited power. In some embodiments, LEDs (110) of differing colors or wavelengths may be used to signal specific conditions.

The system may be incorporated into various garments or accessories, including shirts, jackets, vests, wristbands, headbands, harnesses (400), helmets, belts, or pet collars. In aquatic embodiments, water-resistant sealants (103, 111, 300) and encapsulants ensure reliable operation in wet environments, including swimming or diving. In rugged embodiments, additional enclosures (301) or flexible spreaders (200, 201) may be employed to improve impact resistance and durability.

Overall, the implementation combines innovative use of thermoelectric technology, efficient energy harvesting, and ultra-low power control circuitry to provide a practical, wearable safety device. This method represents an advancement in wearable electronics, providing a self-sufficient power source through the body's natural heat, eliminating reliance on external power sources or batteries. The apparatus exemplifies a sustainable approach to increasing pedestrian, cyclist, or pet safety during nighttime or low-visibility activities.

The embodiments described herein illustrate representative implementations of the invention but are not intended to be limiting. Features disclosed in relation to one embodiment may be combined with features of another, and variations may be made in garment type, thermoelectric generator (100) configuration, circuit topology, or control methodology without departing from the scope of the invention. The system may be scaled for different applications, ranging from single-LED (110) safety strobes to multi-LED arrays (205) with advanced driver sequencing.

The foregoing description has presented representative embodiments of both apparatus and methods for a body-heat-powered wearable strobe light system. These embodiments are provided by way of example only and are not intended to limit the invention to the particular forms disclosed. Variations, modifications, and functional equivalents may be employed without departing from the scope and spirit of the invention. Accordingly, the claims are intended to encompass not only the specific structures and processes described herein, but also all equivalents, substitutions, and obvious variations thereof that fall within their scope.

1. A wearable strobe-light system, comprising:
a thermoelectric generator (TEG) configured to convert a wearer's body heat into electrical power;
an energy harvester circuit operatively coupled to the TEG and configured to condition and optimize the harvested electrical output;
an energy storage element electrically coupled to the harvester;
an oscillator and driver circuit powered by the energy storage element; and
one or more lighting devices operatively coupled to the driver circuit and configured to emit a visible strobe effect.

2. A method of operating a wearable strobe-light system powered by body heat, comprising:
generating electrical power from body heat using a thermoelectric generator (TEG);
harvesting and conditioning the electrical power using an energy harvester circuit;
storing harvested energy in an energy storage element;
supplying energy from the storage element to an oscillator and driver circuit; and
driving one or more lighting devices to produce a strobe effect.

3. The system of claim 1, wherein the TEG comprises a modular multi-stage design with multiple thermoelectric modules stacked in thermal series.

4. The system of claim 3, wherein adjacent thermoelectric modules are thermally coupled by a thermal interface material (TIM) selected from the group consisting of pads, pastes, compounds, and thermally conductive adhesives.

5. The system of claim 1, wherein the TEG comprises multiple coupled pairs of P-type and N-type semiconductor pellets electrically connected in series and thermally connected in parallel.

6. The system of claim 5, wherein the pellets are positioned between thermally conductive, electrically insulating substrates selected from ceramics, polymer films, or coated metallic foils.

7. The system of claim 1, wherein a thermally insulating sealant is applied to sidewalls of the TEG to suppress lateral heat leakage, improve water resistance, and bond the TEG to the garment.

8. The system of claim 1, wherein a heat sink or heat spreader of high thermal conductivity material is coupled to the TEG to enhance heat collection and rejection.

9. The system of claim 1, wherein the oscillator comprises an astable multivibrator implemented using a comparator or operational amplifier with a hysteresis resistor network and reference voltage to establish upper and lower switching thresholds.

10. The system of claim 9, wherein the hysteresis thresholds define the charge and discharge cycle of the energy storage element to control the strobe frequency and brightness.

11. The system of claim 1, wherein the oscillator and driver circuit further comprise a switching transistor that powers the lighting device, the transistor selected from low-gate-charge, low on-resistance MOSFETs.

12. The system of claim 1, wherein the strobe frequency is controlled by adjusting the charging and discharging rate of a capacitor between two threshold voltages established by the oscillator.

13. The system of claim 1, wherein a strobe frequency varies adaptively with the rate of harvested energy, producing slower strobes under low-power conditions and faster strobes under high-power conditions.

14. The system of claim 1, wherein the lighting device comprises one or more light-emitting diodes (LEDs).

15. The system of claim 14, wherein multiple LEDs are individually addressable and driven by independent circuits.

16. The system of claim 14, wherein the LEDs are sequenced or phase-shifted to increase peak brightness while maintaining average power efficiency.

17. The system of claim 1, wherein the garment comprises multiple layers of fabric forming an electronics compartment.

18. The system of claim 17, wherein the compartment contains the energy storage element, circuit boards, and interconnect wires.

19. The system of claim 1, wherein the thermal resistance of the TEG is optimized relative to the combined thermal resistances between the wearer's body and the TEG, and between the TEG and the ambient environment.

20. The system of claim 1, wherein the garment is selected from the group consisting of shirts, jackets, vests, pants, socks, wristbands, headbands, harnesses, belts, and helmets.
